(19) United States
(12) Patent Application Publication
(10) Pub. No.: US 2009/0140438 A1
(43) Pub. Date: Jun. 4, 2009

(54) SEMICONDUCTOR DEVICE AND MANUFACTURING METHOD THEREOF

(75) Inventors: Shunpei YAMAZAKI, Setagaya (JP); Hideaki KUWABARA, Isehara (JP)

Correspondence Address: ERIC ROBINSON, PMB 955, 21010 SOUTHBANK ST., POTOMAC FALLS, VA, 20165, US

(73) Assignee: SEMICONDUCTOR ENERGY LABORATORY CO., LTD., Atsugi-shi (JP)

(21) Appl. No.: 12/325,474

(22) Filed: Dec. 1, 2008

(30) Foreign Application Priority Data
Dec. 3, 2007 (JP) 2007-312818

(51) Int. Cl. H01L 23/535; H01L 21/027

(52) U.S. Cl. 257/776; 257/784; 438/694; 438/708; 257/E23.168; 257/E21.023

(57) ABSTRACT

Wirings each having a side face with a different angle, which is made accurately, in a desired portion over one mother glass substrate are provided without increasing the steps. With the use of a multi-tone mask, a photoresist layer is formed, which has a tapered shape in which the area of a cross section is reduced gradually in a direction away from one mother glass substrate. At the time of forming one wiring, one photomask is used and a metal film is selectively etched, whereby one wiring having a side face, the shape (specifically, an angle with respect to a principal plane of a substrate) of which is different depending on a place, is obtained.

### BACKGROUND OF THE INVENTION

1. Field of the Invention

The present invention relates to a semiconductor device having a circuit including a thin film transistor (hereinafter referred to as a TFT) and to a manufacturing method thereof. For example, the present invention relates to an electronic device provided with, as a component, an electro-optical device typified by a liquid crystal display panel or a light-emitting display device having an organic light-emitting element.

Note that in this specification, a semiconductor device means any device which can function by utilizing semiconductor characteristics, and an electro-optical device, a semiconductor circuit, and an electronic device are all included in the semiconductor device.

2. Description of the Related Art

In recent years, a technique for forming a thin film transistor (TFT) by using a semiconductor thin film (having a thickness of approximately several to several hundreds of nanometers) formed over a substrate having an insulating surface has been attracted attention. Thin film transistors are widely applied to electronic devices such as ICs and electro-optic devices, and development of thin film transistors as switching elements particularly for image display devices has been urgently required.

In particular, active matrix display devices (such as liquid crystal display devices or light-emitting display devices), in which a switching element of a TFT is provided for each of display pixels arranged in a matrix, have been actively developed.

In order to display a high-definition image, formation of switching elements for the image display device needs a high-definition photolithography technique which can arrange the switching elements with high area efficiency.

In addition, a production technology where one mother glass substrate is cut into separate sections to obtain a plurality of panels so that mass production is efficiently performed has been employed. The size of a mother glass substrate is 300 mm×400 mm for the first generation in the beginning of 1990s, which has increased to 680 mm×880 mm or 730 mm×920 mm for the fourth generation in 2000s. Production technologies have progressed so that a number of display panels can be obtained from one substrate. In the future, the size of a mother glass substrate will be further increased; therefore, it is necessary to apply to a substrate with a size that exceeds 3 m of the tenth generation, for example.

In order to obtain a display device that can display a high-definition image, a wiring is formed by performing etching on a metal thin film formed over a mother glass substrate with the use of a resist mask which can be obtained by a photolithography technique.

There are various etching methods, which can be roughly divided into a dry etching method and a wet etching method. Since the wet etching method is employed for isotropic etching, the side face of a wiring layer protected with a resist mask is cut off to some extent; thus, the wet etching method is not suitable for miniaturization.

In addition, an RIE etching method, which is employed for anisotropic etching, is generally known as the dry etching method. Since the RIE etching method is employed for anisotropic etching, it is advantageous in miniaturization as compared to the wet etching method which is employed for isotropic etching.

Moreover, a tungsten wiring having a cross-sectional tapered shape using an ICP etching apparatus is disclosed in Patent Document 1: Japanese Published Patent Application No. 2001-35808.

In addition, in Patent Document 2: Japanese Published Patent Application No. 2002-151523, a manufacturing process for a TFT is described in which a photomask or a reticle provided with a diffraction grating pattern or an auxiliary pattern having a function of reducing light intensity, which is formed of a semi-transmissive film, is applied to a photolithography step for forming a gate electrode.

Further, a technique of making a cross-sectional shape of a wiring partially different by adjusting a resist mask width and an etching condition is disclosed in Patent Document 3: Japanese Published Patent Application No. 2006-13461.

Furthermore, a technique of forming a source or drain electrode with the use of a photomask provided with an auxiliary pattern having a function of reducing light intensity, which is formed of a semi-transmissive film, is disclosed in Patent Document 4: Japanese Published Patent Application No. 2007-133371.

### SUMMARY OF THE INVENTION

In the case of forming wirings over one mother glass substrate by the conventional method, wirings each having the same cross-sectional shape are formed. For example, when an RIE dry etching is employed, the developed resist is heated and dissolved to transform the resist shape and then the resist shape is reflected by etching to have a wiring, the side face of which is tapered. In this case, the step of heating a resist is additionally required. In addition, since the area of the resist is increased by dissolving the resist, it is difficult to make narrow the distance between adjacent wirings. Moreover, when there is a wiring below a region where a wiring is to be formed in the case of forming a multilayer wiring, the lower wiring is also heated in dissolving a resist; therefore, the heating temperature of the resist becomes nonuniform and the proportion that the resist dissolves and spreads is changed depending on a place; thus, it is difficult to obtain a desired wiring shape.

In addition, when an ICP etching apparatus is used, it is difficult to obtain a uniform discharge over the entire surface of one rectangular mother glass substrate because a coil-shaped antenna is used.

For example, in a pixel portion of a transmission-type liquid crystal display device, when a gate wiring is formed in a tapered shape, a thin semiconductor layer is formed over the gate wiring, whereas the width of the wiring is increased; therefore, there is a concern that reduction in aperture ratio might be induced. Further, since the width of the wiring is increased when the wiring has a tapered shape, unnecessary parasitic capacitance is formed when there is another wiring overlapping with the wiring with an insulating film interposed therebetween. If the layout of a wiring in each layer is made so that the wirings disposed in different layers do not overlap with each other in order to reduce this parasitic capacitance, reduction in aperture ratio is induced.

In addition, in the case of using the photomask provided with a diffraction grating pattern or an auxiliary pattern having a function of reducing light intensity, which is formed of a semi-transmissive film, the cross-sectional shape of a wiring can be made selectively different. In this case, there are two kinds of cross-sectional shapes of a portion of the wiring, the side face of which has two-step shape, and a portion of the wiring, the side face of which does not have two-step shape.

In a method for manufacturing a semiconductor device, it is an object of the present invention to provide wirings each having a side face with a different angle, which is made accurately, in a desired portion over one mother glass substrate without increasing the steps.

A light-transmitting substrate and a light-exposure mask are used. The light-transmitting substrate can transmit exposure light, and the light-exposure mask includes a light-shielding portion and a semi-transmissive portion having a function of reducing light intensity, which are formed over the light-transmitting substrate. The light-shielding portion is formed of chromium or the like, and in the semi-transmissive portion having a function of reducing light intensity, lines of a light-shielding material and spaces are repeatedly formed with respective predetermined line widths. A light-exposure mask including a semi-transmissive portion formed by lines and spaces is also referred to as a gray-tone light-exposure mask, and light exposure using this light-exposure mask is also referred to as gray-tone light exposure.

The gray-tone light-exposure mask has an opening pattern in which at least one pattern such as a slit or a dot is arranged periodically or non-periodically. Note that the light intensity of an auxiliary pattern having a function of reducing light intensity, which includes a mask opening space formed of lines and spaces less than or equal to the resolution limit of a light-exposure apparatus, can be controlled in the range of 10% to 70%.

In addition, a light-exposure mask including a semi-transmissive portion formed of a semi-transmissive film having a function of reducing the light intensity of exposure light is also referred to as a half-tone light-exposure mask, and light exposure using this light-exposure mask is also referred to as half-tone light exposure. As the semi-transmissive film, MoSi, MoSiO, MoSiON, CrSi, or the like can be used in addition to MoSiN.

Note that in this specification, a gray-tone light-exposure mask and a half-tone light-exposure mask are collectively referred to as a multi-tone mask, for convenience.

With the use of a multi-tone mask, a photoresist layer is formed, which has a tapered shape in which the area of a cross section is reduced gradually in a direction away from one mother glass substrate. In the present invention, one step is not formed on both of the ends of one photoresist layer, but the photoresist layer is developed to have two different thicknesses by using a gray-tone light-exposure mask or a half-tone light-exposure mask.

In the present invention, at the time of forming one wiring, one photomask is used, and gray-tone light-exposure (or half-tone light-exposure) is performed on a first region and normal light exposure is performed on a second region at the same time. After that, development is performed and a metal film is selectively etched, whereby one wiring having a side face, the shape (specifically, an angle with respect to a principal plane of a substrate) of which is different depending on a place, is obtained. According to this method, the shape of the side face of the wiring can be intentionally made different, and practitioners can obtain a desired wiring.

Consequently, the width of the side face (also referred to as the width of a tapered portion) of the wiring in the first region is larger than the width of the side face of the wiring in the second region. In addition, an angle of the side face with respect to the principal plane of the substrate in the first region is narrower than that in the second region.

It is preferable that, in one wiring, a difference between angles of the side faces with respect to the principal plane of the substrate in the first region and the second region is made at least greater than 10°.

For example, in a transmission-type liquid crystal display device, a thin film transistor having excellent electric characteristics is formed in a first region which serves as a gate electrode overlapping with a semiconductor layer, and the width of a tapered portion is reduced in a second region which serves as a gate wiring extending between pixel electrodes, whereby an aperture ratio is improved. In addition, in order to reduce the wiring resistance and improve the aperture ratio, the width of the tapered portion of the gate wiring is preferably reduced. Note that the total width of the gate wiring is larger than the total width of the gate electrode, so that the wiring resistance can be reduced.

In a structure of the present invention disclosed in this specification, a semiconductor device includes a semiconductor layer over a substrate and a wiring partially overlapping with the semiconductor layer, in which the wiring includes a region where the width of a wiring side portion is large and a region where the width of a wiring side portion is small, and the region where the width of a wiring side portion is large overlaps with at least part of the semiconductor layer and an angle of the side face in a cross section in a wiring width direction is smaller than that of the region where the width of a wiring side portion is small by greater than or equal to 10°.

Specifically, the angle of the side face in a cross section in a wiring width direction of the region where the width of a wiring side portion is large is in the range of 10° to 50°, and the angle of the side face in a cross section in a wiring width direction of the region where the width of a wiring side portion is small is in the range of 60° to 90°. Note that the cross-sectional shape of the wiring is a rectangle or a square if the angle of the side face in a cross section in a wiring width direction is 90°, and the cross-sectional shape of the wiring is a trapezoid in which an upper base is shorter than a lower base if the angle is less than 90°.

In an inverted staggered thin film transistor, a semiconductor layer formed over a gate wiring has a thickness of approximately 50 nm, which is thin; therefore, an angle of the side face in a cross section in a wiring width direction of a region where the width of a gate wiring side portion is large is preferably in the range of 10° to 50° so that part of the semiconductor layer which overlaps with the end portion or the side face of the gate wiring is not thinned.

The present invention solves at least one of the problems described above.

In addition, the present invention can also be used in the case of forming other wirings such as a source wiring, a drain wiring, or a connection wiring over an interlayer insulating film, without limitation on the gate wiring.

Moreover, not only a wiring having side faces with the same angle on both ends at end portions of the wiring in a cross section can be formed, but also an angle between one side face and a principal plane of a substrate can be made different from an angle between the other side face and the principal plane of the substrate. In this case, the cross-sectional shape of the wiring is a trapezoid in which two interior angles with respect to the lower base are different from each other.

In another structure of the present invention, a semiconductor device includes a first wiring over a substrate, an insulating film covering the first wiring, and a second wiring electrically connected to the first wiring with the insulating film interposed therebetween, in which, between two end portions of the second wiring in the cross-sectional shape, an angle of one side face with respect to a principal plane of the substrate is different from an angle of the other side face with respect to the principal plane of the substrate.

Further, in another structure in addition to the structures described above, a semiconductor device includes a transparent conductive film partially overlapping with the second wiring, in which, between two end portions of the second wiring in the cross-sectional shape, one side face where an angle with respect to the principal plane of the substrate is narrow is in contact with the transparent conductive film. With such a structure, electrical connection to the transparent conductive film which overlaps with one side face of the second wiring can be certainly performed, whereby disconnection of the transparent conductive film is reduced.

In addition, in another structure of the present invention, one photoresist layer is developed to have three or more different thicknesses by using a gray-tone light-exposure mask or a half-tone light-exposure mask, and two or more steps are formed on both of the ends of the photoresist layer. When a conductive layer is etched using the photoresist layer as a mask, the cross-sectional shape of a wiring which is obtained has a stair shape in which one side face has two or more steps. It is needless to say that the wiring having the cross-sectional shape can be formed selectively. Therefore, a semiconductor device can be obtained in which a first wiring and a second wiring having a cross-sectional shape different from that of the first wiring are formed over the same insulating film surface, a cross-sectional shape of the first wiring is a rectangle or a trapezoid, the cross-sectional shape of the second wiring is a stair shape in which one side face has two or more steps, and the first wiring and the second wiring are formed of the same material. When the cross-sectional shape of the wiring has a tapered shape, there is a concern that the position of the tapered end portion might be affected by etching time, and variation in total wiring width might be caused particularly when a taper angle is set less than 60°, or a concern that the side face might have a curved surface and spread toward the bottom, which leads to reduction in cross-sectional area and increase in wiring resistance. However, a constant wiring width can be obtained by forming a wiring in a stair shape even when etching time is slightly different. In other words, a sufficient margin of an etching condition can be obtained by making the cross-sectional shape of the second wiring having a stair shape. Further, the second wiring is formed to have an end portion having two steps in the cross-sectional shape, so that almost the same step coverage as that of the wiring having a tapered shape, the taper angle of which is less than 50°, can be ensured.

Note that in one wiring, a cross-sectional shape of a first region can be a rectangle or a trapezoid, and a cross-sectional shape of a second region can be a stair shape having two or more steps on one side face.

In addition, a structure of the present invention regarding one manufacturing method for realizing the structures described above is a method for manufacturing a semiconductor device including the steps of forming a conductive layer over a substrate, performing light exposure once using a multi-tone mask and developing a first resist mask and a second resist mask which are different in an angle between a side face in a cross section and the principal plane of the substrate, and forming wirings by etching the conductive layer using the first resist mask and the second resist mask as masks, in which, after the development, a difference between an angle on the side face of the first resist mask and an angle on the side face of the second resist mask is greater than 10°.

A structure of the present invention regarding another manufacturing method is a method for manufacturing a semiconductor device including the steps of forming a conductive layer over a substrate, performing light exposure once using a multi-tone mask and developing a first resist mask and a second resist mask which are different in an angle between a side face in a cross section and a principal plane of the substrate, and forming a wiring by etching the conductive layer using the first resist mask and the second resist mask as masks, in which, after the development, a difference between an angle on the side face of the first resist mask and an angle on the side face of the second resist mask is greater than 10°.

In each of the manufacturing methods described above, the cross-sectional shape of the first resist mask is a rectangle or a trapezoid, and the cross-sectional shape of the second resist mask is a trapezoid. Alternatively, in each of the manufacturing methods described above, the cross-sectional shape of the first resist mask is a rectangle or a trapezoid, and the cross-sectional shape of the second resist mask is a stair shape in which one side face has two or more steps.

These means described above are not just matters of design but matters invented as a result of careful examination by the inventors after actually forming a wiring with the use of a multi-tone mask.

In the technique disclosed in Patent Document 1, an angle on a side face of a wiring is determined by an etching condition of an ICP apparatus; therefore, the shapes of side faces of wirings which are formed over the same substrate in the same etching step are intended to be constant in all wirings. Thus, the technique disclosed in Patent Document 1 largely differs from the present invention in which the shapes of side faces of wirings are made intentionally different depending on a place.

Moreover, in the techniques disclosed in the Patent Documents 2 and 4, the side portion of a resist mask has a stair shape, and the side face of a wiring also has a stair shape by reflecting the shape of the resist mask. The wiring disclosed in Patent Documents 2 and 4 has one step on both of the ends.

Further, the technique disclosed in Patent Document 3 is a technique of making the cross-sectional shapes of wirings partially different; however, wirings which are formed in the same etching step each have the same angle between a side face and a principal plane of a substrate.

Note that in this specification, a word which expresses up, down, side, perpendicular, horizontal, or the like indicates a direction based on a surface of the substrate in the case where a device is disposed on the substrate surface.

In addition, in this specification, a gate electrode refers to a portion in which a channel of thin film transistor is formed and which overlaps with a semiconductor layer with an gate insulating film interposed therebetween, and a gate wiring refers to a portion other than the gate electrode. Note that part of one pattern formed of the same conductive material is a gate electrode, and a portion other than the gate electrode refers to a gate wiring.

In addition, in the present invention, a semiconductor film containing silicon as its main component or a semiconductor film containing metal oxide as its main component can be used for a semiconductor layer. As for the semiconductor film containing silicon as its main component, an amorphous semiconductor film, a semiconductor film including a crystalline structure, a compound semiconductor film including an amorphous structure, or the like, specifically amorphous silicon, microcrystalline silicon, polycrystalline silicon, single crystal silicon, or the like can be used. As for the semiconductor film containing metal oxide as its main component, zinc oxide (ZnO), oxide of zinc, gallium, and indium (In—Ga—Zn—O), or the like can be used.

In addition, regardless of a TFT structure and a transistor structure, the present invention can be applied and, for example, a top gate TFT, a bottom gate (inverted staggered) TFT, or a forward stagger TFT can be used. Moreover, without limitation on a transistor having a single-gate structure, a multi-gate transistor having a plurality of channel formation regions, for example, a double gate transistor may be used.

It is possible to manufacture wirings each having a side face with a different angle, which is made accurately, in a desired portion over one mother glass substrate by using one mask, without increasing the steps.

### BRIEF DESCRIPTION OF THE DRAWINGS

In the accompanying drawings:

FIGS. 1A to 1D are cross-sectional views illustrating a manufacturing process of a semiconductor device;

FIGS. 2A to 2C are each a photograph illustrating an example of a cross section of a wiring;

FIGS. 3A to 3D are cross-sectional views illustrating a manufacturing process of a semiconductor device;

FIGS. 4A and 4B are each a photograph illustrating an example of a cross section of a wiring;

FIGS. 5A, 5C, and 5D are each a top view illustrating part of a mask, and FIGS. 5B and 5E are each a schematic diagram illustrating an example of a relationship of light intensity;

FIGS. 6A to 6C are cross-sectional views illustrating a manufacturing process of a semiconductor device;

FIGS. 7A to 7C are cross-sectional views illustrating a manufacturing process of a semiconductor device;

FIGS. 8A to 8C are cross-sectional views illustrating a manufacturing process of a semiconductor device;

FIGS. 9A to 9D are cross-sectional views illustrating a manufacturing method of the present invention;

FIGS. 10A to 10D are cross-sectional views illustrating a manufacturing method of the present invention;

FIGS. 11A to 11C are cross-sectional views illustrating a manufacturing method of the present invention;

FIG. 12 is a top view illustrating a manufacturing method of the present invention;

FIG. 13 is a diagram illustrating an example of a time chart describing the steps of forming a microcrystalline silicon film;

FIG. 14 is a cross-sectional view illustrating an etching apparatus;

FIGS. 15A to 15C are cross-sectional views illustrating a manufacturing process of a semiconductor device;

FIGS. 16A and 16B are cross-sectional views illustrating a manufacturing process of a semiconductor device;

FIGS. 17A to 17C are cross-sectional views illustrating a manufacturing process of a semiconductor device;

FIGS. 18A and 18B are cross-sectional views illustrating a manufacturing process of a semiconductor device;

FIGS. 19A to 19C are cross-sectional views illustrating a manufacturing process of a semiconductor device;

FIG. 20 is a cross-sectional view illustrating an example of a liquid crystal display device;

FIG. 21 is a top view illustrating an example of a liquid crystal display device;

FIG. 22 is a top view illustrating an example of a liquid crystal display device;

FIG. 23 is an equivalent circuit diagram of a pixel of a liquid crystal display device;

FIG. 24 is a cross-sectional view illustrating an example of a liquid crystal display device;

FIG. 25 is a view illustrating an example of a liquid crystal display device;

FIGS. 26A to 26C are perspective views each illustrating a display panel;

FIGS. 27A and 27B are respectively a top view and a cross-sectional view describing a display panel; and

FIGS. 28A to 28C are perspective views each illustrating an electronic device.

### DETAILED DESCRIPTION OF THE INVENTION

Embodiment modes of the present invention will be described below.

### Embodiment Mode 1

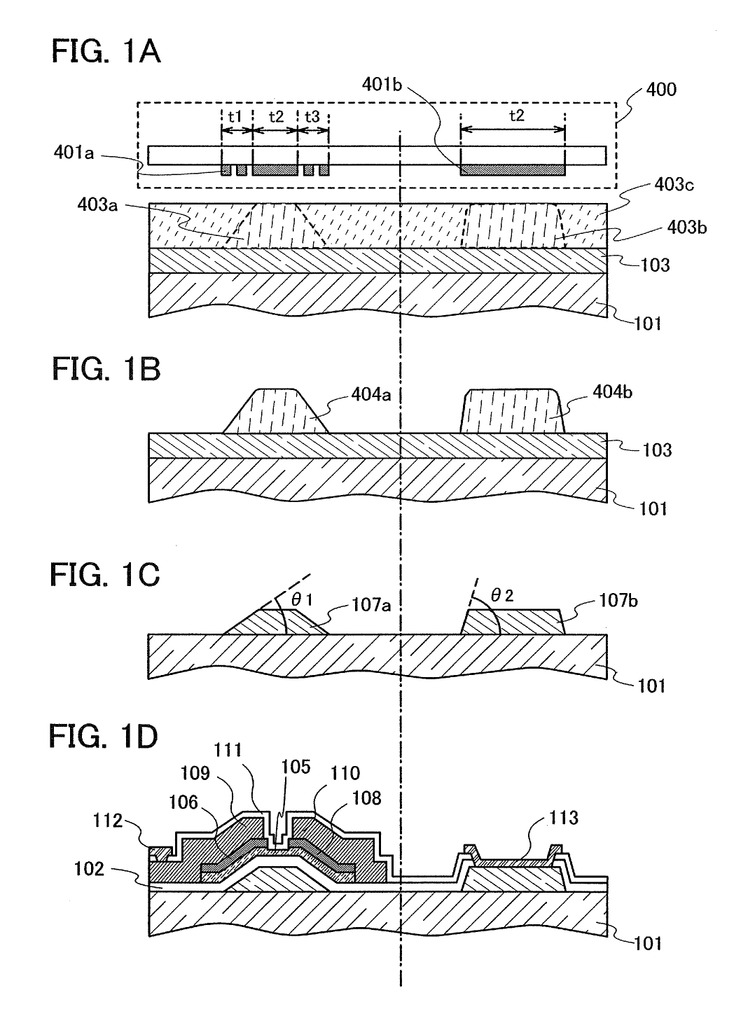

In this embodiment mode, a manufacturing process of forming, over the same substrate, a pixel portion having a thin film transistor and a terminal portion having a connection wiring for connecting it with an external device with the use of an FPC or the like is shown in FIGS. 1A to 1D.

First, a substrate 101 having an insulating surface is prepared. As the substrate 101 having an insulating surface, a light-transmitting substrate, for example, a glass substrate, a crystallized glass substrate, or a plastic substrate can be used. When the substrate 101 is a mother glass, any of the following sizes of the substrate can be used: the first generation (320 mm×400 mm), the second generation (400 mm×500 mm), the third generation (550 mm×650 mm), the fourth generation (680 mm×880 mm or 730 mm×920 mm), the fifth generation (1000 mm×1200 mm or 1100 mm×1250 mm), the sixth generation (1500 mm×1800 mm), the seventh generation (1900 mm×2200 mm), the eighth generation (2160 mm×2460 mm), the ninth generation (2400 mm×2800 mm or 2450 mm×3050 mm), the tenth generation (2950 mm×3400 mm), and the like.

Besides, as long as the substrate 101 having an insulating surface has an insulating surface as the outermost layer or film, the substrate 101 having an insulating surface may have been already provided with a base film formed of an insulator, a semiconductor layer, or a conductive film.

Next, a first conductive layer 103 is formed over the substrate 101 having an insulating surface. The first conductive layer 103 is formed of a refractory metal such as tungsten, titanium, chromium, tantalum, or molybdenum; or an alloy or a compound containing a refractory metal as its main component, such as tantalum nitride, to have a thickness of 200 nm to 600 nm. In addition, in order to reduce the wiring resistance, a metal film such as aluminum, gold, or copper may be stacked with the refractory metal described above.

Then, after the entire surface of the first conductive layer 103 is coated with a resist film 403, light exposure is performed using a mask 400 shown in FIG. 1A. Here, a resist film having a thickness of 1.5 μm is coated, and a light-exposure machine in which resolution is 1.5 μm is used for the light exposure. Alternatively, light used for the light exposure is an i-line (wavelength: 365 nm), and the light exposure energy is selected from a range of 70 mJ/cm to 140 mJ/cm². Without limitation on the i-line, light in which the i-line, a g-line (wavelength: 436 nm), and an h-line (wavelength: 405 nm) are mixed may be used for the light exposure.

In this embodiment mode, a light-exposure mask partially provided with an auxiliary pattern (a gray tone) having a function of reducing light intensity is used as a first photomask so that the taper angle of a gate electrode of a thin film transistor in a pixel portion is in the range of 10° to 50°.

In FIG. 1A, the light-exposure mask 400 has a light-shielding portion 401b formed of a metal film such as Cr and, as the auxiliary pattern having a function of reducing light intensity, a semi-transmissive portion 401a provided with a slit. In the cross-sectional view of the light-exposure mask 400, t2 indicates the width of the light-shielding portion 401b, and t1 and t3 indicate the widths of the semi-transmissive portions 401a. Although an example in which a gray tone is used as part of the light-exposure mask is shown here, a half tone using a semi-transmissive film may also be used.

When the light exposure is performed on the resist film 403 by using the light-exposure mask 400 shown in FIG. 1A, a light-unexposed region 403a, a light-unexposed region 403b, and a region 403c which is exposed to light are formed. At the time of the light exposure, the region 403c which is exposed to light shown in FIG. 1A is formed by light that goes around the light-shielding portions 401b or passes through the semi-transmissive portions 401a.

Then, the region 403c which is exposed to light is removed after the development, and a first resist mask 404a and a second resist mask 404b are obtained respectively in a pixel portion and a terminal portion, over the first conductive layer 103, as shown in FIG. 1B. A light-exposure condition such as light-exposure energy is adjusted, whereby, instead of the end portion having one step, the first resist mask 404a having a tapered shape can be obtained. In the terminal portion which is light-exposed with the photomask in a region without a gray tone, the second resist mask 404b having a wider angle of the side face in the cross section than that of the first resist mask 404a is formed.

Next, the first conductive layer 103 is etched by dry etching using the resist masks 404a and 404b as masks. Note that depending on the etching condition, the substrate 101 having an insulating surface is also etched and partially thinned. Therefore, in advance, an insulating film which is etched may be formed at the outermost surface of the substrate 101 or over the substrate 101. For the etching gas, tetrafluoride (CF₄), sulfur fluoride (SF₆), chlorine (Cl₂), or oxygen (O₂) is used. In addition, a dry etching apparatus is used with which uniform discharge can be easily obtained over a large area as compared to an ICP etching apparatus. As such an etching apparatus, an ECCP (enhanced capacitively coupled plasma) mode apparatus is optimal in which an upper electrode is grounded, a high-frequency power source of 13.56 MHz is connected to a lower electrode, and further a low-frequency power source of 3.2 MHz is connected to the lower electrode. This etching apparatus, if used, can be applied even when, as the substrate 101, a substrate the size of which exceeds 3 m of the tenth generation is used, for example.

After the etching step described above, the remaining resist masks are removed by an ashing treatment or the like. As shown in FIG. 1C, a first wiring layer 107a and a second wiring layer 107b are thus formed over the substrate 101. Here, the first wiring layer 107a formed in the pixel portion has a taper angle θ1 which is set approximately 50°, and the second wiring layer 107b formed in the terminal portion has a taper angle θ2 which is set approximately 70°. A semiconductor film and a wiring are formed over the first wiring layer 107a in a subsequent step; therefore, it is effective to process the taper angles of both of the side faces narrow in order to prevent disconnection. In addition, the plurality of second wiring layers 107b are arranged adjacent to each other and connected to an FPC or the like; therefore, it is effective to process the taper angles of both of the side faces wide so that a short circuit is not caused between the adjacent second wiring layers 107b. Further, when the plurality of second wiring layers 107b are desirable to be arranged in a small area, the distance between the adjacent second wiring layers 107b can be reduced; therefore, it is effective to process the taper angles of both of the side faces wide.

Note that since it is difficult to employ a negative type resist to the resist film used in the etching step of the first conductive layer 103, the pattern structure of a photomask or a reticle for forming a gate electrode is based on a positive type resist.

Next, a gate insulating film 102 of silicon nitride (dielectric constant: 7.0, thickness: 300 nm) is stacked over the first wiring layer 107a. The gate insulating film 102 can be formed by a CVD method, a sputtering method, or the like using a silicon nitride film or a silicon nitride oxide film. Note that, here, a silicon nitride oxide film is a film that contains more nitrogen than oxygen, and includes oxygen, nitrogen, silicon, and hydrogen at concentrations ranging from 15 atomic % to 30 atomic %, 20 atomic % to 35 atomic %, 25 atomic % to 35 atomic %, and 15 atomic % to 25 atomic %, respectively.

Then, after the gate insulating film 102 is deposited, the substrate is transferred without being exposed to the atmosphere to deposit a semiconductor film 105 in a vacuum chamber which is different from a vacuum chamber for depositing the gate insulating film.

Subsequently, after the amorphous semiconductor film 105 is deposited, the substrate is transferred without being exposed to the atmosphere to deposit a semiconductor film to which an impurity imparting one conductivity type is added in a vacuum chamber which is different from the vacuum chamber for depositing the amorphous semiconductor film 105.

As for the semiconductor film to which an impurity imparting one conductivity type is added, phosphorus may be added as a typical impurity element, and an impurity gas such as a phosphine gas may be added to silicon hydride. The semiconductor film to which an impurity imparting one conductivity type is added is formed with a thickness greater than or equal to 2 nm and less than or equal to 50 nm. By forming the semiconductor film to which an impurity imparting one conductivity type is added with a small thickness, throughput can be improved.

Next, a resist mask is formed over the semiconductor film to which an impurity imparting one conductivity type is added. The resist mask is formed by a photolithography technique or an inkjet method. Here, the resist mask is formed by exposing to light and developing a resist with which the semiconductor film to which an impurity imparting one conductivity type is added is coated, using a second photomask.

Then, the semiconductor film to which an impurity imparting one conductivity type is added and the amorphous semiconductor film 105 are etched using the resist mask to form an island-like semiconductor layer. After that, the resist mask is removed.

Next, a second conductive layer is formed so as to cover the semiconductor film to which an impurity imparting one conductivity type is added and the gate insulating film 102. The second conductive layer is preferably formed with a single layer or a stacked layer of aluminum or an aluminum alloy to which an element to improve heat resistance or an element to prevent a hillock, such as copper, silicon, titanium, neodymium, scandium, or molybdenum, is added. Here, although not shown, a conductive film where three layers are stacked is used as the second conductive layer. A molybdenum film is used for each of the first layer and the third layer of the second conductive layer, and an aluminum film is used for the second layer thereof. The second conductive layer is formed by a sputtering method or a vacuum evaporation method.

Then, as shown in FIG. 1D, a resist mask is formed over the second conductive layer using a third photomask, and part of the second conductive layer is etched to form a pair of a source or drain electrode 109 and a source or drain electrode 110. When the second conductive layer is etched by wet etching, the end portion of the second conductive layer is selectively etched. Consequently, the source or drain electrodes 109 and 110, the areas of which are smaller than that of the resist mask, can be formed.

Next, the semiconductor film to which an impurity imparting one conductivity type is added is etched using the resist mask without change to form a pair of a source or drain region 106 and a source or drain region 108. Further, in the etching step, part of the amorphous semiconductor film 105 is also etched. The source or drain regions and the recessed portion (the groove) of the amorphous semiconductor film 105 can be formed in the same step. By forming the recessed portion (the groove) of the amorphous semiconductor film 105 with a depth which is half to one-third the thickness of a region having the largest thickness of the amorphous semiconductor film 105, the source or drain regions can be separated from each other. Therefore, leakage current between the source or drain regions can be reduced. After that, the resist mask is removed.

Then, an insulating film 111 which covers the source or drain electrodes 109 and 110, the source or drain regions 106 and 108, the amorphous semiconductor film 105, and the gate insulating film 102 is formed. The insulating film 111 can be formed by using the same deposition method as the gate insulating film 102. Note that the gate insulating film 102 is formed to prevent intrusion of a contamination impurity such as an organic matter, a metal, or water vapor included in the air; thus, a dense film is preferably used for the gate insulating film 102.

Through the steps described above, a thin film transistor can be formed in the pixel portion.

Next, with the use of a resist mask which is formed using a fourth photomask, the insulating film 111 is selectively etched to form a first contact hole in the pixel portion, which exposes the source or drain electrode 109, and the insulating film 111 and the gate insulating film 102 are selectively etched to form a second contact hole in the terminal portion, which exposes the second wiring layer 107b. The resist mask is removed after the contact holes are formed.

Then, after a transparent conductive film is formed, part of the transparent conductive film is etched using a resist mask which is formed using a fifth photomask to form a pixel electrode 112 in the pixel portion, which is electrically connected to the source or drain electrode 109, and to form a connection electrode 113 in the terminal portion, which is electrically connected to the second wiring layer 107b. The resist mask is removed after the pixel electrode 112 and the connection electrode 113 are formed. A cross-sectional view up through these steps is shown in FIG. 1D.

Further, for the transparent conductive film, a light-transmitting conductive material such as indium oxide containing tungsten oxide, indium zinc oxide containing tungsten oxide, indium oxide containing titanium oxide, indium tin oxide containing titanium oxide, indium tin oxide, indium zinc oxide, or indium tin oxide to which silicon oxide is added can be used. Further, a conductive composition containing a conductive macromolecule (also referred to as a conductive polymer) can be used for the transparent conductive film. The pixel electrode 112 formed of the conductive composition preferably has a sheet resistance which is less than or equal to 10000 ohm/square and a light transmittance which is greater than or equal to 70% at a wavelength of 550 nm. Further, the resistance of the conductive macromolecule included in the conductive composition is preferably less than or equal to 0.1 Ω·cm.

As the conductive macromolecule, a so-called π-electron conjugated conductive macromolecule can be used. As examples thereof, polyaniline or a derivative thereof, polypyrrole or a derivative thereof, polythiophene or a derivative thereof, a copolymer of two or more kinds of these materials, and the like can be given.

Through the above process, an element substrate which can be used for a transmission-type liquid crystal display device can be formed.

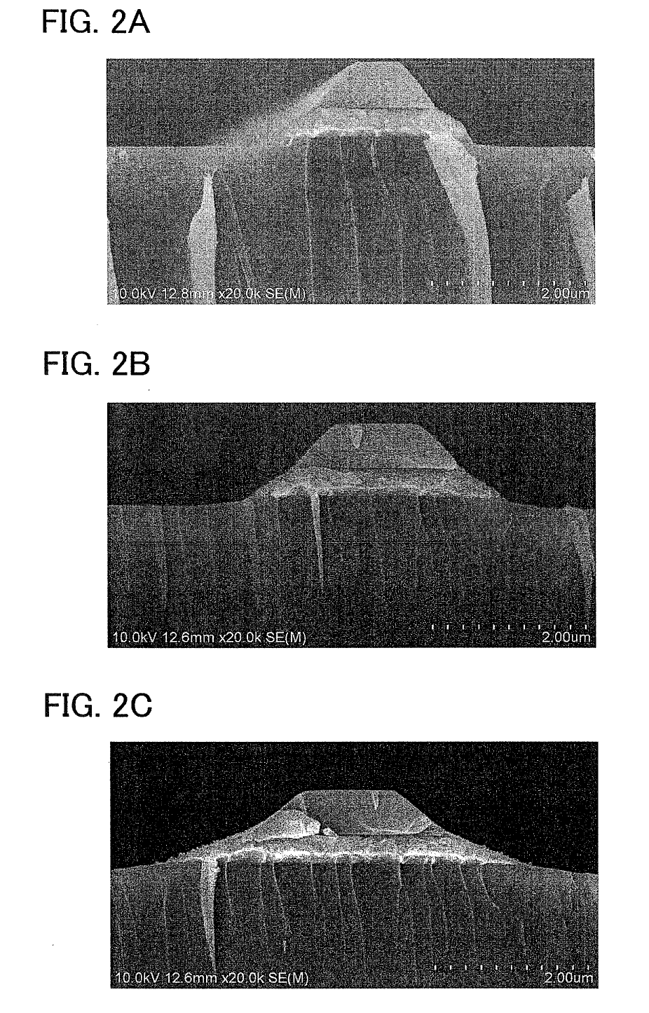

In addition, an experiment is performed, and FIGS. 2A to 2C show the cross-sectional SEM photographs of a wiring which is obtained by etching using a gray-tone mask.

As a sample, a silicon oxynitride film having a thickness of 100 nm was deposited over a glass substrate, and a titanium film having a thickness of 400 nm was deposited over the silicon oxynitride film. Then, a resist film was formed over the titanium film.

The resist film was light-exposed and developed using the light-exposure machine with the resolution of 1.5 μm. After that, as a first etching condition, flow rates of a BCl₃ gas and a Cl₂ gas were both set 40 sccm and etching was performed for 65 seconds. Then, as a second etching condition, flow rates of a BCl₃ gas and a Cl₂ gas were respectively set 70 sccm and 10 sccm, and etching was performed.

The cross section of the wiring in a region without the gray tone corresponds to FIG. 2A. The width of the light-shielding portion is 3 μm. The taper angle of the wiring in FIG. 2A is approximately 50°.

In addition, the cross section of a wiring in a region which is exposed to light using a gray-tone mask in which the line width is 0.5 μm and the space width is 0.5 μm corresponds to FIG. 2B. The width of a light-shielding portion is 3 μm. The taper angle of the wiring in FIG. 2B is approximately 40°.

Moreover, the cross section of a wiring in a region which is exposed to light using a gray-tone mask in which both the line width of 0.5 μm and the space width of 0.5 μm are repeated twice corresponds to FIG. 2C. The width of a light-shielding portion is 3 μm. The taper angle of the wiring in FIG. 2C is approximately 30°.

Even when the widths of the light-shielding portions are thus the same, a wiring width and a taper angle which can be obtained depending on the line width or the space width of each gray tone can be made different. Note that when an experiment is performed in which the line width or the space width of a gray tone is changed, there may be a wiring shape having one step on the side face or a wiring shape having a projected portion.

Although the experiment was performed here under the etching conditions described above, without particular limitation thereto, it is preferable that the design of a mask or etching conditions be adjusted as appropriate by the practitioners so that a resist having a taper angle which is different can be obtained by light exposure and development, and that a wiring reflecting the resist shape can be obtained.

### Embodiment Mode 2

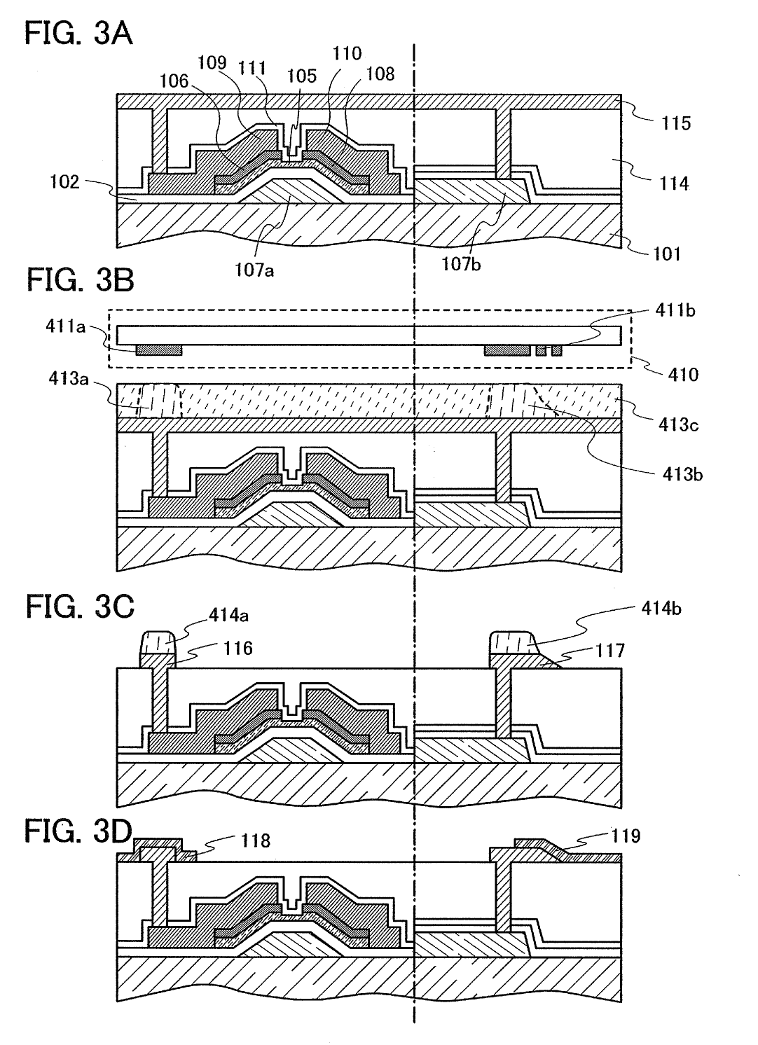

In this embodiment mode, an example will be described, in which cross-sectional shapes of a pixel portion and a terminal portion are made different at the time of forming a wiring over an interlayer insulating film which covers a thin film transistor, with reference to FIGS. 3A to 3D.

Note that since steps in the middle of a manufacturing process are the same as steps in Embodiment Mode 1, the detailed descriptions are omitted here. In addition, in FIGS. 3A to 3D, description will be made using the same reference numerals for the portions that are common to those in FIGS. 1A to 1D.

This embodiment mode shows an example of forming a planarization film over the insulating film 111 which covers the thin film transistor formed in Embodiment Mode 1.

First, steps up to and including the step of forming the insulating film 111 are performed in accordance with Embodiment Mode 1.

Next, a planarization film 114 is formed. The planarization film 114 is formed of an organic resin film. Then, with the use of the resist mask which is formed using the fourth photomask, the insulating film 111 and the planarization film 114 are selectively etched to form a first contact hole in the pixel portion, which exposes the source or drain electrode 109, and the gate insulating film 102, the insulating film 111, and the planarization film 114 are selectively etched to form a second contact hole in the terminal portion, which exposes the second wiring layer 107b.

Then, a third conductive layer 115 is formed over the planarization film 114. A process cross-sectional view up to this stage corresponds to FIG. 3A.

Next, after the entire surface of the third conductive layer 115 is coated with a resist film, light exposure is performed using a mask 410 shown in FIG. 3B.

In this embodiment mode, a light-exposure mask partially provided with an auxiliary pattern (a gray tone) having a function of reducing light intensity is used as the fourth photomask so that the taper angle of one of side faces of the connection electrode in the terminal portion is in the range of 10° to 50°.

In FIG. 3B, the light-exposure mask 410 has a light-shielding portion 411a formed of a metal film such as Cr and, as the auxiliary pattern having a function of reducing light intensity, a semi-transmissive portion 411b provided with a slit. Although an example in which a gray tone is used as part of the light-exposure mask is shown here, a half tone using a semi-transmissive film may also be used.

When the light exposure is performed on the resist film by using the light-exposure mask 410 shown in FIG. 3B, a light-unexposed region 413a, a light-unexposed region 413b, and a region 413c which is exposed to light are formed. At the time of the light exposure, the region 413c which is exposed to light shown in FIG. 3B is formed by light that goes around the light-shielding portion 411a or passes through the semi-transmissive portions 411b.

Then, the region 413c which is exposed to light is removed after the development, and a third resist mask and a fourth resist mask are obtained respectively in the pixel portion and the terminal portion, over the third conductive layer 115. A light-exposure condition such as light-exposure energy is adjusted, whereby, instead of the end portion having one step, the fourth resist mask having a tapered shape on one of the side faces can be obtained.

Next, the third conductive layer 115 is etched by dry etching using the third resist mask and the fourth resist mask as masks. In addition, a dry etching apparatus is used with which uniform discharge can be easily obtained over a large area as compared to an ICP etching apparatus. As such an etching apparatus, an ECCP (enhanced capacitively coupled plasma) mode apparatus is optimal in which an upper electrode is grounded, a high-frequency power source of 13.56 MHz is connected to a lower electrode, and further a low-frequency power source of 3.2 MHz is connected to the lower electrode. This etching apparatus, if used, can be applied even when, as the substrate 101, a substrate, the size of which exceeds 3 m of the tenth generation, is used, for example.

A process cross-sectional view up to this stage corresponds to FIG. 3C. The third resist mask and the fourth resist mask are etched when the third conductive layer 115 are etched, and a third resist mask 414a and a fourth resist mask 414b remain over a first connection electrode 116 and a second connection electrode 117, respectively. The second connection electrode 117 reflects the shape of the fourth resist mask to have a tapered shape only on one side face. In addition, in the pixel portion which is light-exposed with the photomask in a region without a gray tone, etching is performed so that the area of the first connection electrode 116 is reduced, which can contribute to improvement in aperture ratio.

After the etching step described above, the remaining resist masks are removed by an ashing treatment or the like.

Next, after a transparent conductive film is formed, part of the transparent conductive film is etched using the resist mask which is formed using the fifth photomask to form a pixel electrode 118 in the pixel portion, which covers the first connection electrode 116 to be electrically connected thereto, and to form a third connection electrode 119 in the terminal portion, which is electrically connected to the second connection electrode 117. The resist mask is removed after the pixel electrode 118 and the third connection electrode 119 are formed. A cross-sectional view up through these steps corresponds to FIG. 3D. The third connection electrode 119 is provided to overlap with the taper shape of the second connection electrode 117, whereby prevention of disconnection of the third connection electrode 119 is achieved.

Through the above process, an element substrate which can be used for a transmission-type liquid crystal display device can be formed.

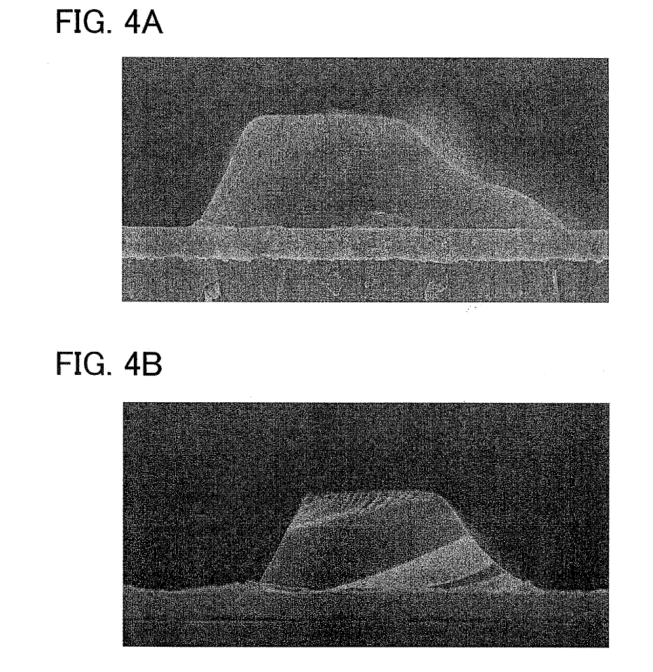

In addition, an experiment is performed, and FIGS. 4A and 4B show the cross-sectional SEM photographs of a wiring which is obtained by etching using a gray-tone mask.

As a sample, a silicon oxynitride film having a thickness of 100 nm was deposited over a glass substrate, and a titanium film having a thickness of 400 nm was deposited over the silicon oxynitride film. Then, a resist film was formed over the titanium film.

The resist film was light-exposed and developed using the light-exposure machine with the resolution of 1.5 μm. After that, as a first etching condition, flow rates of a BCl₃ gas and a Cl₂ gas were both set 40 sccm and etching was performed for 65 seconds. Then, as a second etching condition, flow rates of a BCl₃ gas and a Cl₂ gas were respectively set 70 sccm and 10 sccm, and etching was performed.

As shown in the photomask of FIG. 3B, the cross section of a wiring in a region which is exposed to light using a gray-tone mask in which both the line width of 0.5 μm and the space width of 0.5 μm are repeated twice only on one side corresponds to FIG. 4A. One taper angle is approximately 70°, and the other taper angle is approximately 35°.

In addition, the cross section of a wiring in a region which is exposed to light using a gray-tone mask in which the line width of 0.5 μm and the space width of 0.75 μm are arranged only on one side corresponds to FIG. 4B. One taper angle is approximately 70°, and one side face, which is smoother than the other side face, has different taper angles. One side face has a taper angle close to the substrate which is approximately 30° and a taper angle far from the substrate which is approximately 60°.

Note that when light exposure is performed using a gray-tone mask in which both the line width of 0.5 μm and the space width of 0.5 μm are repeated three times only on one side, a wiring shape having one step on the side face was obtained. If the line width and the space width change in such a manner, the wiring shape which is obtained changes largely. Therefore, it is important for the practitioners to achieve optimization of etching conditions by selecting a line width and a space width which are optimal.

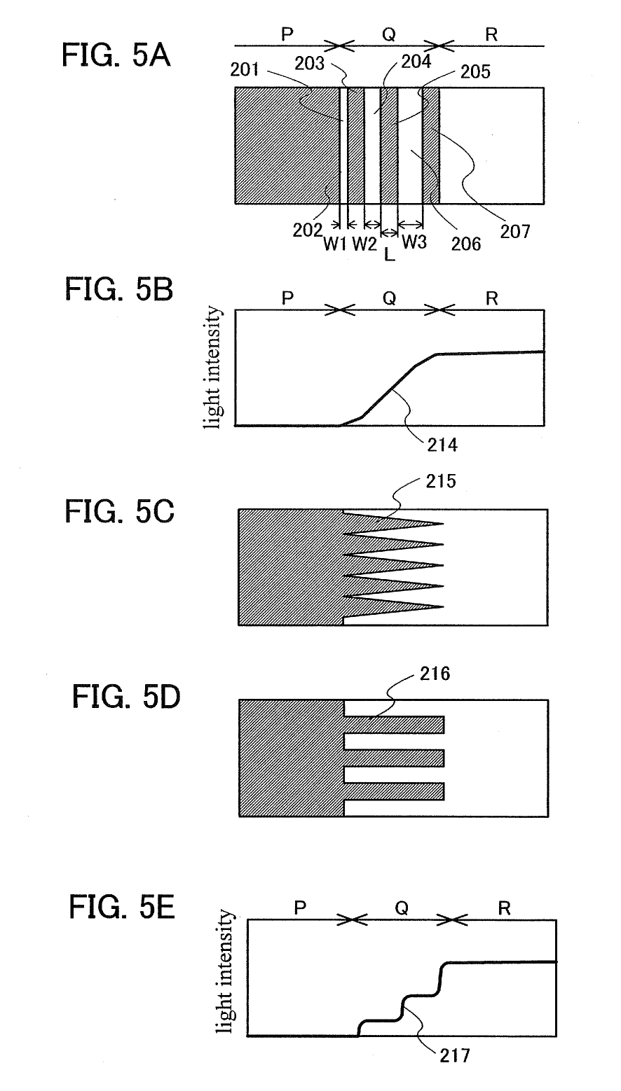

In addition, an example of a light-exposure mask including a semi-transmissive portion formed by lines and spaces, or rectangular patterns and spaces is described with reference to FIGS. 5A to 5E.

Specific example of a top view of a light-exposure mask is shown in FIG. 5A. In addition, an example of a light intensity distribution 214 when the light-exposure mask is used is shown in FIG. 5B. The light-exposure mask shown in FIG. 5A includes a light-shielding portion P, a semi-transmissive portion Q, and a transmissive portion R. In the semi-transmissive portion Q of the light-exposure mask shown in FIG. 5A, a line 203, a line 205, and a line 207 and a space 201, a space 204, and a space 206 are repeatedly provided in stripes (in slits), and the lines and the spaces are arranged parallel to an end portion 202 of the light-shielding portion P. In this semi-transmissive portion, a width of the line 205 formed of a light-shielding material is L and a width of the space 204 between light-shielding materials is W2. The line 203 is formed of a light-shielding material and can be formed using the same light-shielding material as the light-shielding portion P. Although the line 203 is formed in a rectangular shape, the shape is not limited thereto. It is acceptable as long as the line 203 has a constant width. For example, the line 203 may have a shape with round corners.

In the light-exposure mask of FIG. 5A, the width W2 of the space 204 is larger than a width W1 of the space 201, and a width W3 of the space 206 is larger than the width W2 of the space 204. In addition, the lines in the light-exposure mask of FIG. 5A have the same width.

Note that the light-exposure mask of FIG. 5A is one example, and there is no particular limitation as long as the light intensity distribution shown in FIG. 5B can be obtained. For example, as shown in FIG. 5C, a light-exposure mask having a light-shielding portion 215, the end of which has an acute angle instead of a line, is used to perform light exposure to obtain the light intensity distribution shown in FIG. 5B. In addition, a light-exposure mask having a light-shielding portion 216 provided with a plurality of branch portions as shown in FIG. 5D is used, and the light intensity distribution shown in FIG. 5B is obtained.

This embodiment mode can be freely combined with Embodiment Mode 1.

### Embodiment Mode 3

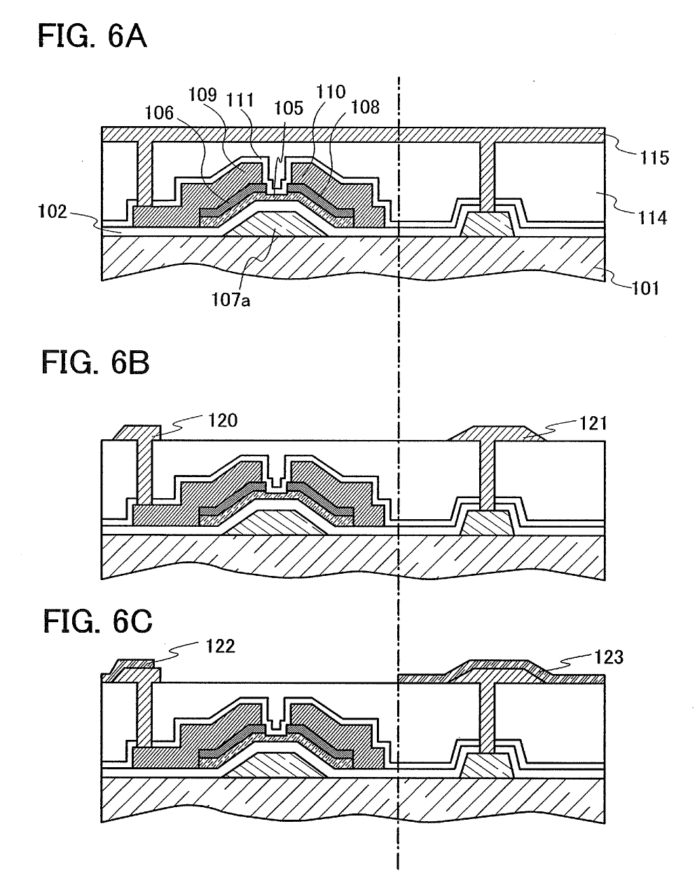

In this embodiment mode, a partially different example of Embodiment Mode 2 will be described with reference to FIGS. 6A to 6C. Since FIG. 6A is the same as FIG. 3A, the detailed descriptions are omitted here and the same reference numerals are denoted for the same portions.

In accordance with Embodiment Mode 2, steps up to and including the step of forming the third conductive layer 115 are performed, which are the same stage as FIG. 6A.

Next, the third conductive layer 115 is selectively etched using a photomask which is different from that of Embodiment Mode 2. In this embodiment mode, an example is shown in which a first connection electrode 120 having a taper angle only on one side is formed in a pixel portion, and a second connection electrode 121 having the same taper angle on both of the sides is formed in a terminal portion.

After the etching step described above, the remaining resist masks are removed by an ashing treatment or the like.

Next, after a transparent conductive film is formed, part of the transparent conductive film is etched using a resist mask which is formed using the fifth photomask to form a pixel electrode 122 in the pixel portion, which partially overlaps with the first connection electrode 120 to be electrically connected thereto, and to form a third connection electrode 123 in the terminal portion, which is electrically connected to the second connection electrode 121.

In this embodiment mode, the pixel electrode 122 is provided to overlap with the taper shape of the first connection electrode 120, whereby prevention of disconnection of the pixel electrode 122 is achieved.

Through the above process, an element substrate which can be used for a transmission-type liquid crystal display device can be formed.

This embodiment mode can be freely combined with Embodiment Mode 1 or 2.

### Embodiment Mode 4

In this embodiment mode, an example will be shown in which a light-exposure mask provided with an auxiliary pattern (a halftone film) having a function of reducing light intensity, which is formed of a semi-transmissive film, is used.

First, in a manner similar to that of Embodiment Mode 1, the first conductive layer 103 is formed over the substrate 101, and a resist film is formed over the first conductive layer 103.

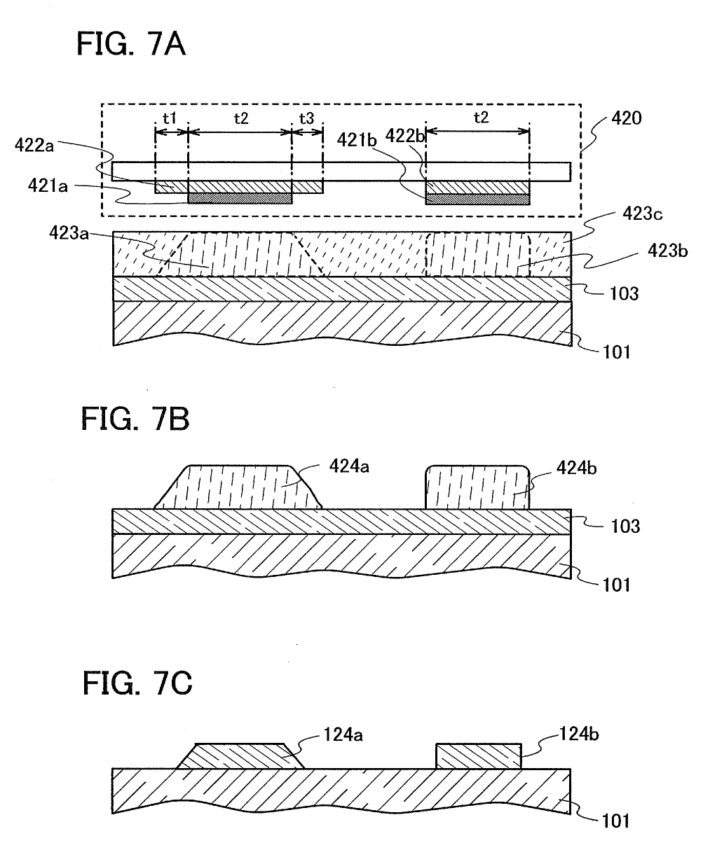

In FIG. 7A, a light-exposure mask 420 has a light-shielding portion 421a and a light-shielding portion 421b each formed of a metal film such as Cr and, as the auxiliary pattern having a function of reducing light intensity, portions (also referred to as a semi-transmissive portion 422a and a semi-transmissive portion 422b) provided with a semi-transmissive film (also referred to as a half-tone film). In the cross-sectional view of the light-exposure mask 420, t2 indicates the width of a region in which the light-shielding portion 421b and the semi-transmissive portion 422b overlap with each other in the light-shielding portion 421b and the semi-transmissive portion 422b, and t1 and t3 indicate the widths of one layer in the semi-transmissive portion 422a. That is, t1 and t3 indicate the widths of a region in which the light-shielding portion 421a does not overlap with the semi-transmissive portion 422a.

When the light exposure is performed on the resist film by using the light-exposure mask 420 shown in FIG. 7A, a light-unexposed region 423a, a light-unexposed region 423b, and a region 423c which is exposed to light are formed. At the time of the light exposure, the region 423c which is exposed to light shown in FIG. 7A is formed by light that goes around the light-shielding portions 421a and 421b or passes through the semi-transmissive portions 422a and 422b.

Then, the region 423c which is exposed to light is removed after the development, and a resist mask 424a having a taper shape on both sides and a resist mask 424b, the cross section of which is almost rectangular, are obtained over the first conductive layer 103, as shown in FIG. 7B.

Next, the first conductive layer 103 is etched by dry etching using the resist masks 424a and 424b as masks.

After the etching step described above, the remaining resist masks are removed by an ashing treatment or the like. As shown in FIG. 7C, a first wiring layer 124a and a second wiring layer 124b are thus formed over the substrate 101. Here, the first wiring layer 124a formed in the pixel portion has a taper angle which is set approximately 60°, and the second wiring layer 124b formed in the terminal portion has a taper angle which is set approximately 90°.

In the following steps, a thin film transistor is formed in accordance with Embodiment Mode 1, and an element substrate which can be used for a transmission-type liquid crystal display device is formed.

This embodiment mode can be freely combined with Embodiment Mode 1, 2, or 3.

### Embodiment Mode 5

In this embodiment mode, an example is shown in which, as wirings, three kinds of a cross-sectional shape having two steps, a cross-sectional shape of a trapezoid, and a cross-sectional shape having one step are formed with the same mask.

First, in a manner similar to that of Embodiment Mode 1, the first conductive layer 103 is formed over the substrate 101, and a resist film is formed over the first conductive layer 103.

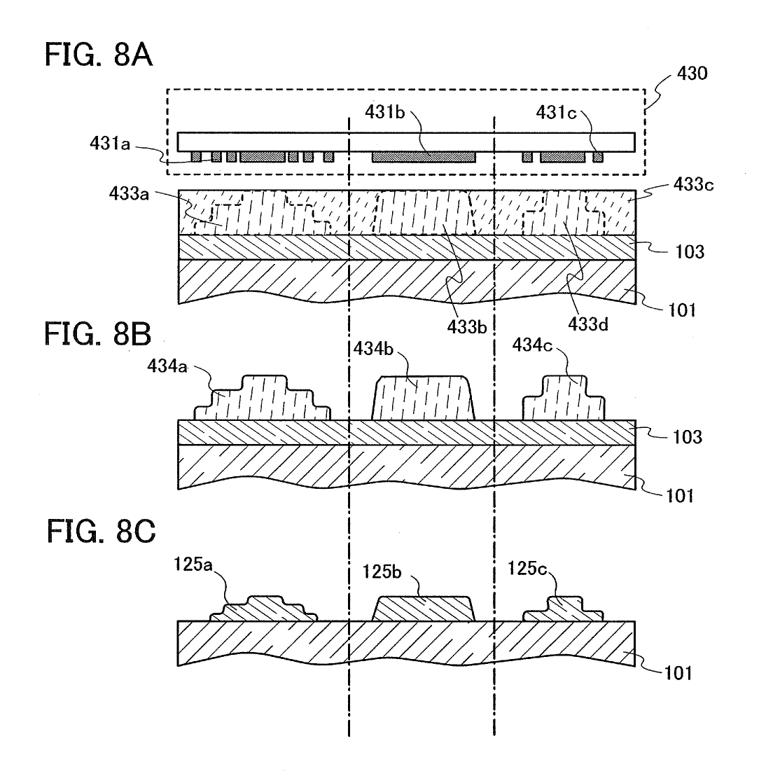

Next, the resist film is light-exposed using a light-exposure mask 430 shown in FIG. 8A. When light exposure is performed on the resist film, a light-unexposed region 433a, a light-unexposed region 433b, a light-unexposed region 433d, and a region 433c which is exposed to light are formed. At the time of the light exposure, the region 433c which is exposed to light shown in FIG. 8A is formed by light that goes around a light-shielding portion 431b or passes through a semi-transmissive portion 431a and a semi-transmissive portion 431c.

In this embodiment mode, a light-exposure mask partially provided with an auxiliary pattern (a gray tone) having a function of reducing light intensity is used as a first photomask to form two steps on both sides of a gate electrode of a thin film transistor in the pixel portion. As the first photomask, a light-exposure mask in which both sides of the light-shielding portion are provided with the pattern shown in FIG. 5A is used. By changing the line width, the space width, or the light-exposure condition, a distribution which is different from the light intensity distribution shown in FIG. 5B, for example, a light intensity distribution 217 shown in FIG. 5E, by which two steps are formed, is obtained. Note that the light-exposure mask shown in FIG. 5A is one example, for example, as shown in FIG. 5C, the light-exposure mask having the light-shielding portion 215, the end of which has an acute angle instead of a line, may be used to perform light exposure to obtain the light intensity distribution shown in FIG. 5E. In addition, the light-exposure mask having the light-shielding portion 216 provided with a plurality of branch portions as shown in FIG. 5D may be used to obtain the light intensity distribution shown in FIG. 5E.

In addition, one step is formed on both of the ends of a connection electrode of the terminal portion. The step is formed using the semi-transmissive portion 431c which is different from the semi-transmissive portion of the gate electrode of a thin film transistor in the pixel portion.

Then, the region 433c which is exposed to light is removed after the development, and a first resist mask 434a, a second resist mask 434b, and a third resist mask 434c are obtained respectively in the pixel portion, a gate wiring portion of the pixel portion, and the terminal portion, over the first conductive layer 103, as shown in FIG. 8B. A light-exposure condition such as light-exposure energy is adjusted, whereby the first resist mask 434a having two steps on the end portion can be obtained. In the gate wiring portion of the pixel portion which is light-exposed with the photomask in a region without a gray tone, the second resist mask 434b having a trapezoid shape is formed. In addition, in the terminal portion, the third resist mask 434c having one step on the end portion can be obtained.

Next, the first conductive layer 103 is etched by dry etching using the resist masks 434a, 434b, and 434c as masks.

After the etching step described above, the remaining resist masks are removed by an ashing treatment or the like. As shown in FIG. 8C, a first wiring layer 125a, a second wiring layer 125b, and a third wiring layer 125c are thus formed over the substrate 101. Here, the first wiring layer 125a formed in the pixel portion has an end portion having two steps, the second wiring layer 125b formed in the gate wiring portion of the pixel portion has the side face having a trapezoid shape, and the third wiring layer 125c formed in the terminal portion has an end portion having one step. When a tapered shape is employed, there is a concern that the position of the tapered end portion might be affected by etching time, and variation in total wiring width might be caused particularly when a taper angle is set less than 60°. However, a constant wiring width can be obtained by forming a wiring layer having a stair shape even when etching time is slightly different. In other words, a sufficient margin of an etching condition can be obtained by forming the wiring layer having a stair shape. Further, the first wiring layer 125a is formed to have an end portion having two steps, so that almost the same step coverage as that of the wiring layer having a tapered shape, the taper angle of which is less than 50°, can be ensured. Note that the angle of the side face of the second wiring layer 125b which is formed in the gate wiring portion of the pixel portion is in the range of 60° to 90°.

The light-exposure mask 430 is thus designed as appropriate by the practitioners, so that a wiring layer having a desirable shape can be selectively formed.

In the following steps, a thin film transistor is formed in accordance with Embodiment Mode 1, and an element substrate which can be used for a transmission-type liquid crystal display device is formed.

This embodiment mode can be freely combined with Embodiment Mode 1, 2, 3, or 4.

### Embodiment Mode 6

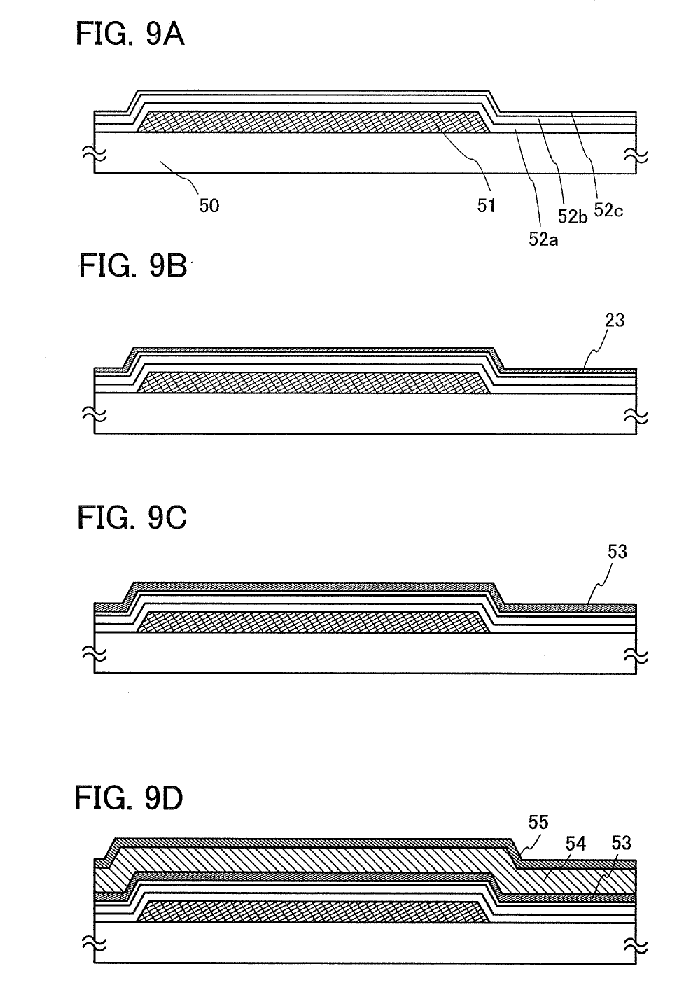

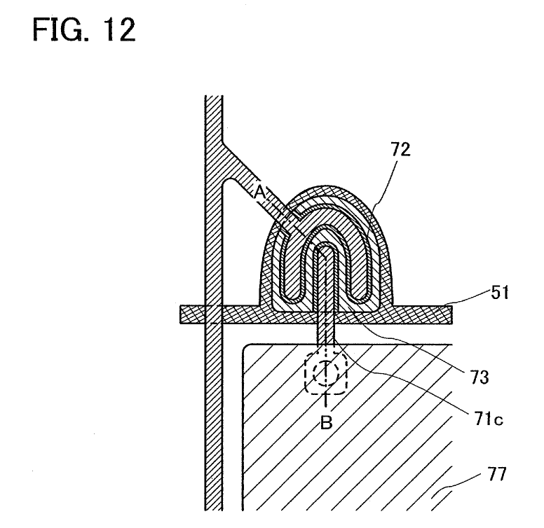

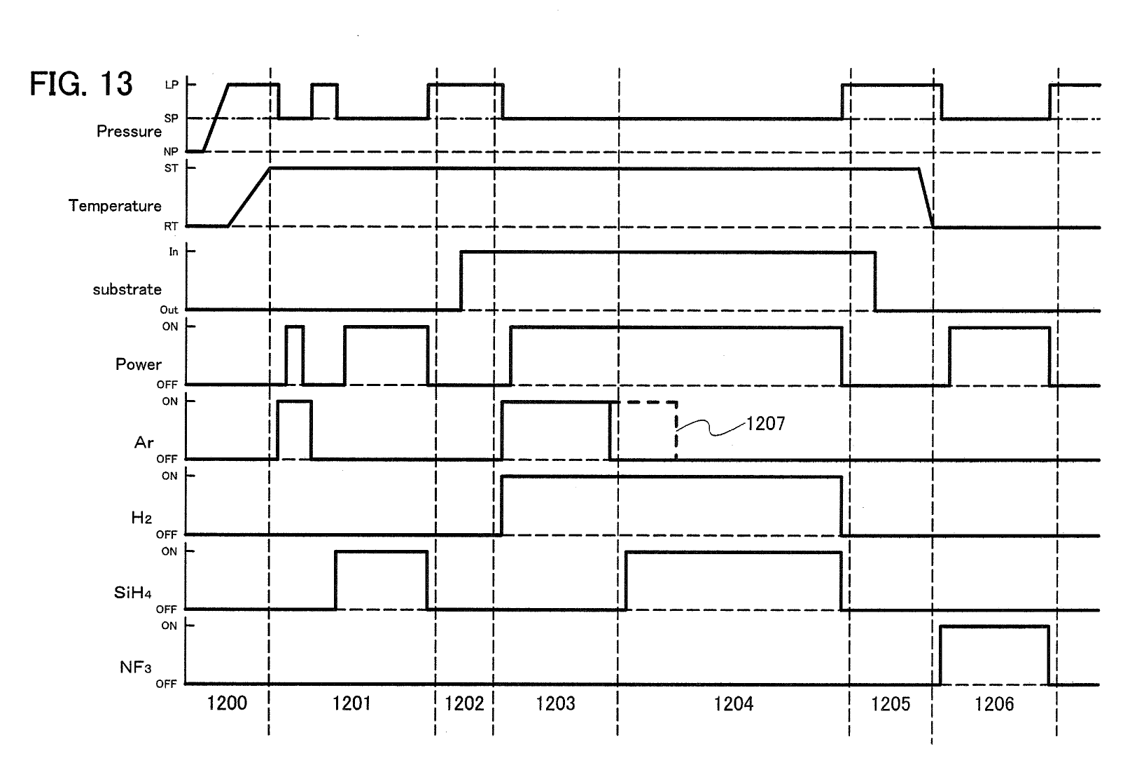

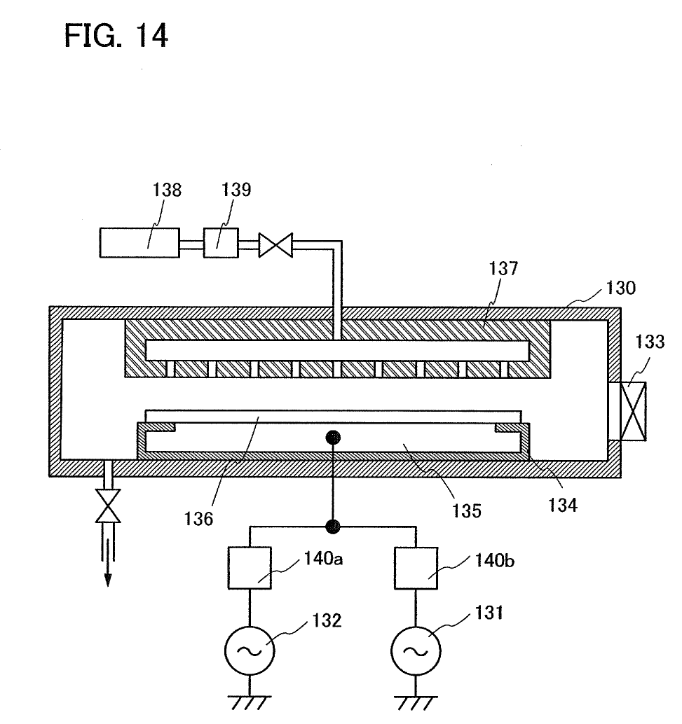

In this embodiment mode, a manufacturing process of a thin film transistor which is used for a liquid crystal display device will be described with reference to FIGS. 9A to 9D, FIGS. 10A to 10D, FIGS. 11A to 11C, FIG. 12, FIG. 13, and FIG. 14. FIGS. 9A to 9D, FIGS. 10A to 10D, and FIGS. 11A to 11C are cross-sectional views showing a manufacturing process of the thin film transistor, and FIG. 12 is a top view showing a connection region of the thin film transistor and a pixel electrode in a single pixel. Further, FIG. 13 is a timing chart showing a formation method of a microcrystalline silicon film. FIG. 14 is a cross-sectional view of an etching apparatus which is used at the time of forming an electrode or a wiring.

A thin film transistor having a microcrystalline semiconductor film, which is of an n-type, is more suitable for use in a driver circuit than that of a p-type because it has a higher mobility. It is preferable that all thin film transistors formed over the same substrate have the same polarity, in order to reduce the number of steps. Here, description is made using an n-channel thin film transistor.

As shown in FIG. 9A, a gate electrode 51 is formed over a substrate 50. As the substrate 50, any of the following substrates can be used: non-alkaline glass substrates made of barium borosilicate glass, aluminoborosilicate glass, aluminosilicate glass, and the like by a fusion method or a float method. When the substrate 50 is a mother glass, any of the following sizes of the substrate can be used: the first generation (320 mm×400 mm), the second generation (400 mm×500 mm), the third generation (550 mm×650 mm), the fourth generation (680 mm×880 mm or 730 mm×920 mm), the fifth generation (1000 mm×1200 mm or 1100 mm×1250 mm), the sixth generation (1500 mm×1800 mm), the seventh generation (1900 mm×2200 mm), the eighth generation (2160 mm×2460 mm), the ninth generation (2400 mm×2800 mm or 2450 mm×3050 mm), the tenth generation (2950 mm×3400 mm), and the like.

The gate electrode 51 is formed using a metal material such as titanium, molybdenum, chromium, tantalum, tungsten, or aluminum, or an alloy material thereof. The gate electrode 51 is formed in the following manner: a conductive film is formed over the substrate 50 by a sputtering method or a vacuum evaporation method, a resist mask is formed over the conductive film with the multi-tone mask shown in Embodiment Mode 1, and the conductive film is etched using the mask. Note that as a barrier metal which improves adhesion of the gate electrode 51 and prevents diffusion to a base, a nitride film of the metal material described above may be provided between the substrate 50 and the gate electrode 51. Here, the gate electrode 51 is formed by etching the conductive film formed over the substrate 50 with the use of the resist mask which is formed using the photomask which is a multi-tone mask, and a wiring (a gate wiring, a lead wiring, a capacitor wiring, or the like), the angle of the side face of which is different from the angle of the side face of the gate electrode, is also formed at the same time.

In addition, the etching is performed here using the etching apparatus shown in FIG. 14.

The etching apparatus shown in FIG. 14 is an ECCP (enhanced capacitively coupled plasma) mode apparatus in which an upper electrode 137 is grounded, a high-frequency power source 132 of 13.56 MHz is connected to a lower electrode 135, and further a low-frequency power source 131 of 3.2 MHz is connected to the lower electrode 135. This etching apparatus, if used, can be applied even when, as the substrate 50, a substrate, the size of which exceeds 3 m of the tenth generation, is used, for example.

In order to introduce a substrate to be processed in a chamber 130, an opening provided on the external wall of the chamber is provided with a gate valve 133, and the gate valve 133 is connected to a load chamber or an unload chamber of a substrate, or a transfer chamber. In addition, the pressure in the chamber 130 can be reduced by a vacuum evacuation unit such as a turbo molecular pump. Moreover, a pair of parallel plate electrodes including an upper electrode 137 and a lower electrode 135 is formed in the chamber 130.

The upper electrode 137 servers as a shower head, which is provided with a plurality of openings for introducing an etching gas in the chamber 130. In addition, the etching gas for which is supplied to a hollow center of the upper electrode 137 is supplied from a gas supply mechanism 139 which is connected through a gas supply tube and the valve. Moreover, the gas supply mechanism 139 is connected to a gas supply source 138.

The periphery and upper periphery of the lower electrode 135 is provided with an insulating member 134. In addition, although not shown, the lower electrode 135 includes a substrate holding unit for holding a substrate 136 to be processed, such as an electrostatic chuck, and a heating unit or a cooling unit for adjusting the temperature. Moreover, the upper electrode 137 may be provided with a heating unit or a cooling unit for adjusting the temperature.

A power supply line is electrically connected to the lower electrode 135, and a first matching box 140a and the high-frequency power source 132 are connected to the power supply line. The high-frequency power source 132 supplies high-frequency power for generating plasma, which is 13.56 MHz, to the lower electrode. In addition, a second matching box 140b and the low-frequency power source 131 are connected to the power supply line. The low-frequency power source 131 supplies low-frequency power of, for example, 3.2 MHz to the lower electrode so as to overlap with the high-frequency power for generating plasma.

In addition, each component of the etching apparatus shown in FIG. 14 is controlled by a process controller. With this etching apparatus, in-plane uniformity can be ensured even when a substrate the size of which exceeds 3 m of the tenth generation is used.

Next, a gate insulating film 52a, a gate insulating film 52b, and a gate insulating film 52c are formed in this order over the gate electrode 51. A cross-sectional view up through these steps corresponds to FIG. 9A.

Each of the gate insulating films 52a, 52b, and 52c can be formed of a silicon oxide film, a silicon nitride film, a silicon oxynitride film, or a silicon nitride oxide film by a CVD method, a sputtering method, or the like. In order to prevent an interlayer short circuit caused by a pinhole or the like formed in the gate insulating films, it is preferable to form plural layers using different insulating layers. Here, a silicon nitride film, a silicon oxynitride film, and a silicon nitride film are stacked in this order as the gate insulating films 52a, 52b, and 52c, respectively.

Here, a silicon oxynitride film is a film that contains more oxygen than nitrogen, and includes oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively.

The thickness of each of a first layer and a second layer of the gate insulating films is to be thicker than 50 nm. It is preferable that the first layer of the gate insulating films be a silicon nitride film or a silicon nitride oxide film in order to prevent diffusion of an impurity (e.g., alkali metal or the like) from the substrate. Further, the first layer of the gate insulating films can prevent oxidation of the gate electrode and can also prevent hillock in the case of using aluminum for the gate electrode. A third layer of the gate insulating films in contact with a microcrystalline semiconductor film is to have a thickness greater than 0 nm and less than or equal to 5 nm, preferably approximately 1 nm. The third layer of the gate insulating films is provided to improve adhesion with the microcrystalline semiconductor film. Further, when the third layer of the gate insulating films is formed of a silicon nitride film, prevention in oxidation of the microcrystalline semiconductor film by a heat treatment which will be performed later can be achieved. For example, if a heat treatment is performed in the state in which an insulating film including a large amount of oxygen is in contact with the microcrystalline semiconductor film, there is a concern that the microcrystalline semiconductor film might be oxidized.

Further, the gate insulating films are preferably formed by a microwave plasma CVD apparatus with a frequency of 1 GHz. A silicon oxynitride film or a silicon nitride oxide film formed by a microwave plasma CVD apparatus has high resistance to voltage, so that reliability of a thin film transistor can be improved.

Although here, the gate insulating films employ a three-layer structure, a single layer of a silicon nitride film may be used in the case where a thin film transistor is used for a switching element of a liquid crystal display device, in which AC driving is performed.

After the gate insulating films are deposited, the substrate is transferred without being exposed to the atmosphere, and a microcrystalline semiconductor film 53 is preferably deposited in a vacuum chamber which is different from a vacuum chamber for depositing the gate insulating films.

A procedure for forming the microcrystalline semiconductor film 53 is described below also with reference to FIG. 13. FIG. 13 shows the procedure starting from a step where vacuum evacuation 200 is performed in the vacuum chamber that is under atmospheric pressure. Then, the following treatments are shown in chronological order: precoating 1201, substrate installation 1202, a base pretreatment 1203, a film formation treatment 1204, substrate removal 1205, and cleaning 1206. Note that the procedure is not limited to performing vacuum evacuation starting from atmospheric pressure, and it is preferable to maintain the vacuum chamber under a certain degree of vacuum at all times in terms of mass production as well as in terms of reducing the ultimate vacuum in a short time.

In this embodiment mode, ultra-high vacuum evacuation is performed in order to achieve a lower degree of vacuum than 10⁻⁵ Pa in the vacuum chamber before the substrate installation. This step corresponds to vacuum evacuation 1200 in FIG. 13. In the case of performing such ultrahigh vacuum evacuation, it is preferable to use a turbo-molecular pump and a cryopump. Evacuation is performed with the turbo-molecular pump, and vacuum evacuation is performed with the cryopump. It is also effective to perform vacuum evacuation with two turbo molecular pumps connected in series. Further, it is preferable to perform a heat treatment by providing a heater for baking in the vacuum chamber and perform a treatment of degassing from the inner wall of the vacuum chamber. Moreover, a heater for heating the substrate is also operated to stabilize the temperature. The substrate heating temperature is 100° C. to 300° C., preferably 120° C. to 220° C.

Next, the precoating 1201 is performed before the substrate installation, and a silicon film is formed as an inner wall coating film. In the precoating 1201, a silane gas is introduced to generate plasma after a gas (an atmospheric component such as oxygen and nitrogen, or an etching gas used in cleaning the vacuum chamber) that is attached to the inner wall of the vacuum chamber is removed by generating plasma by introducing hydrogen or a rare gas. Since a silane gas reacts with oxygen, moisture, or the like, oxygen and moisture in the vacuum chamber can be removed by flowing a silane gas, and further, generating silane plasma. Further, by performing the precoating 1201, a metal element of a member constituting the vacuum chamber can be prevented from entering the microcrystalline silicon film as an impurity. In other words, by covering the inside of the vacuum chamber with silicon, the inside of the vacuum chamber can be prevented from being etched by plasma, and the impurity concentration of the microcrystalline silicon film which will be formed later can be reduced. The precoating 1201 includes a treatment in which the inner wall of the vacuum chamber is covered with a film that is of the same kind as a film to be deposited over the substrate.

After the precoating 1201, the substrate installation 1202 is performed. Since the substrate over which the microcrystalline silicon film will be deposited is stored in a load chamber on which vacuum evacuation has been performed, the degree of vacuum of the vacuum chamber will not deteriorate remarkably even if the substrate is installed therein.

Next, the base pretreatment 1203 is performed. The base pretreatment 1203 is preferably performed because it is particularly effective in the case of forming the microcrystalline silicon film. In other words, in the case of forming a microcrystalline silicon film over a glass substrate surface, an insulating film surface, or an amorphous silicon surface by a plasma CVD method, there is a concern that an amorphous layer might be formed in an initial stage of deposition due to an impurity or lattice mismatch. In order to reduce the thickness of this amorphous layer as much as possible, or to get rid of it if possible, it is preferable to perform the base pretreatment 1203. As the base pretreatment, a rare gas plasma treatment, a hydrogen plasma treatment, or a combination of both treatments is preferable. A rare gas element having a large mass number, such as argon, krypton, or xenon, is preferably used for the rare gas plasma treatment. This is so that an impurity such as oxygen, moisture, an organic substance, or a metal element that is attached to the surface is removed by a sputtering effect. The hydrogen plasma treatment is effective in that, by hydrogen radicals, the above impurity that is adsorbed on the surface is removed, and a clean film formation surface is formed by an etching effect with respect to the insulating film or the amorphous silicon film. Further, by performing both the rare gas plasma treatment and the hydrogen plasma treatment, growth of a microcrystal nucleus is promoted.

In terms of promoting growth of a microcrystal nucleus, it is effective to supply a rare gas such as argon continuously in the initial stage of forming the microcrystalline silicon film, as shown by a broken line 1207 in FIG. 13.

Next, the film formation treatment 1204 for forming the microcrystalline silicon film is performed after the base pretreatment 1203. In this embodiment mode, a microcrystalline silicon film near an interface with the gate insulating film is formed under a first deposition condition in which a deposition rate is low but the quality of a film to be formed is high, and then a microcrystalline silicon film is deposited further under a second deposition condition in which a deposition rate is high.

There is no particular limitation as long as the deposition rate of the second deposition condition is higher than the deposition rate of the first deposition condition. Therefore, the microcrystalline silicon film can be formed by a high-frequency plasma CVD method with a frequency of several tens to several hundreds of megahertz or using a microwave plasma CVD apparatus with a frequency of greater than or equal to 1 GHz. The microcrystalline silicon film can be typically formed by generating plasma by diluting a silicon hydride such as SiH₄, Si₂H₆, or the like with hydrogen. With a dilution with one or plural kinds of rare gas elements selected from helium, argon, krypton, and neon in addition to silicon hydride and hydrogen, the microcrystalline semiconductor film can be formed. In such a case, a flow rate of hydrogen is greater than or equal to 12 times and less than or equal to 1000 times, preferably, greater than or equal to 50 times and less than or equal to 200 times, and more preferably, 100 times as high as that of silicon hydride. Note that instead of silicon hydride, SiH₂Cl₂, SiHCl₃, SiCl₄, SiF₄, or the like can be used.

Further, in the case of adding helium to a source gas, since helium has an ionization energy of 24.5 eV that is the largest among all gases and has a metastable state in the level of approximately 20 eV that is a little lower than the ionization energy, only the difference of approximately 4 eV is necessary for ionization while keeping discharge. Therefore, the discharge starting voltage also shows the lowest value among all gases. By such characteristics, plasma can be held stably with helium. Moreover, since uniform plasma can be generated, the plasma density can be homogenized even if a substrate over which the microcrystalline silicon film is deposited is increased.

Further, an energy band width may be adjusted to 1.5 eV to 2.4 eV or 0.9 eV to 1.1 eV by mixing a hydride of carbon such as CH₄ or C₂H₆, a germanium hydride such as GeH₄ or GeF₄, or a germanium fluoride into a gas such as silane. By adding carbon or germanium to silicon, the temperature characteristics of a TFT can be changed.

Here, under the first deposition condition, silane is diluted greater than 100 times and less than or equal to 2000 times with hydrogen and/or a rare gas, and a heating temperature of the substrate is greater than or equal to 100° C. and less than 300° C., preferably 120° C. to 220° C. It is preferable that deposition be performed at a temperature of 120° C. to 220° C. in order that a growing surface of the microcrystalline silicon film is inactivated with hydrogen, and growth of microcrystalline silicon is promoted.

A cross-sectional view up through the step under the first deposition condition is shown in FIG. 9B. Over the gate insulating film 52c, a microcrystalline semiconductor film 23 is formed, which is formed with a low deposition rate but the quality of a film to be formed is high. The quality of this microcrystalline semiconductor film 23 obtained under the first deposition condition contributes to increasing the on-current and improving the field-effect mobility of a TFT which will be formed later; therefore, it is important to sufficiently reduce an oxygen concentration in the film to an oxygen concentration of less than or equal to 1×10¹⁷/cm. Further, by the above procedure, not only the concentration of oxygen that mixes into the microcrystalline semiconductor film is reduced, but those of nitrogen and carbon can also be reduced; therefore, the microcrystalline semiconductor film can be prevented from being an n-type.

Next, the microcrystalline semiconductor film 53 is formed by changing a deposition rate the deposition rate of the first deposition condition to the deposition rate of the second deposition condition. A cross-sectional view of this stage is shown in FIG. 9C. The thickness of the microcrystalline semiconductor film 53 may be 50 nm to 500 nm (preferably 100 nm to 250 nm). Note that in this embodiment mode, deposition time of the microcrystalline semiconductor film 53 includes a first deposition period, in which deposition is performed under the first deposition condition, and a second deposition period, in which deposition is performed under the second deposition condition.

Here, under the second deposition condition, silane is diluted greater than or equal to 12 times and less than or equal to 100 times with hydrogen and/or a rare gas, and a heating temperature of the substrate is 100° C. to 300° C., preferably 120° C. to 220° C. Note that a microcrystalline silicon film is formed under the following condition: a capacitively coupled (parallel plate) plasma CVD apparatus is used, a gap (a distance between an electrode surface and a substrate surface) is 20 mm, a degree of vacuum in the vacuum chamber is 100 Pa, a substrate temperature is 300° C., 20 W of high-frequency power with a frequency of 60 MHz is applied, and a silane gas (the flow rate of 8 sccm) is diluted 50 times with hydrogen (the flow rate of 400 sccm). In addition, when only the flow rate of a silane gas is changed to 4 sccm and the silane gas is diluted 100 times under the above deposition condition to form a microcrystalline silicon film, the deposition rate gets low. The deposition rate is increased by fixing the flow rate of hydrogen and increasing the flow rate of silane. The crystallinity of the microcrystalline semiconductor film 53 is improved by reducing the deposition rate.

In this embodiment mode, with the use of a capacitively coupled (parallel plate) plasma CVD apparatus, a gap (a distance between an electrode surface and a substrate surface) is set at 20 mm, and a microcrystalline silicon film is formed under the first deposition condition and the second deposition condition. Under the first deposition condition, a degree of vacuum in the vacuum chamber is 100 Pa, substrate temperature is 100° C., 30 W of high-frequency power with a frequency of 60 MHz is applied, and a silane gas (the flow rate of 2 sccm) is diluted 200 times with hydrogen (the flow rate of 400 sccm). Under the second deposition condition for increasing a deposition rate by changing the gas flow rate, a silane gas of 4 sccm is diluted 100 times with hydrogen (the flow rate of 400 sccm) to perform the deposition.

Next, after deposition of the microcrystalline silicon under the second deposition condition is completed, supply of the source gas such as silane and hydrogen, and the high-frequency powers are stopped, and the substrate removal 1205 is performed. In the case of performing the deposition treatment to a subsequent substrate, the same treatment starting from the substrate installation 1202 is performed. The cleaning 1206 is performed to remove a film or powder which is attached to the vacuum chamber.

The cleaning 1206 is performed by plasma etching in such a way that an etching gas typified by NF₃ and SF₆ is introduced. Alternatively, a gas which can etch without using plasma, such as ClF₃, is introduced to perform the cleaning 1206. In the stage of the cleaning 1206, the temperature is preferably lowered by turning off the heater for heating the substrate. This is to suppress generation of a reaction by-product due to etching. After completion of the cleaning 1206, similar treatments as described above may be performed on the subsequent substrate starting from the precoating 1201. Since NF₃ contains nitrogen as its composition, in order to reduce a nitrogen concentration in a film formation chamber, it is preferable to sufficiently reduce the nitrogen concentration by performing the precoating.

Next, after the microcrystalline semiconductor film 53 is deposited, the substrate is transferred without being exposed to the atmosphere, and a buffer layer 54 is preferably deposited in a vacuum chamber which is different from the vacuum chamber for depositing the microcrystalline semiconductor film 53. By having separate vacuum chambers for depositing the buffer layer 54 and depositing the microcrystalline semiconductor film 53, the vacuum chamber for depositing the microcrystalline semiconductor film 53 can be a chamber dedicated to having an ultra-high vacuum prior to introducing the substrate. Accordingly, contamination by an impurity can be suppressed to a minimum, and the time it takes to reach an ultra-high vacuum can be shortened. This is particularly effective in the case of performing baking to reach the ultra-high vacuum, because it takes time for the inner-wall temperature of the chamber to become lower and stable. Furthermore, by having separate vacuum chambers, different frequencies of high-frequency power can be used in accordance with film qualities that are to be obtained.

The buffer layer 54 is formed using an amorphous semiconductor film containing hydrogen or halogen. Further, an amorphous semiconductor film containing hydrogen can also be formed using hydrogen with a flow rate greater than or equal to 1 time and less than or equal to 10 times, preferably greater than or equal to 1 time and less than or equal to 5 times as high as that of silicon hydride. Furthermore, an amorphous semiconductor film containing fluorine, chlorine, bromine, or iodine can be formed using the above silicon hydride and a gas containing fluorine, chlorine, bromine, or iodine (e.g., F₂, Cl₂, Br₂, I₂, HF, HCl, HBr, HI, or the like). Note that instead of silicon hydride, SiH₂Cl₂, SiHCl₃, SiCl₄, SiF₄, or the like can be used.

Alternatively, as the buffer layer 54, an amorphous semiconductor film can be formed by sputtering with hydrogen or a rare gas using an amorphous semiconductor as a target. If a gas containing fluorine, chlorine, bromine, or iodine (e.g., F₂, Cl₂, Br₂, I₂, HF, HCl, HBr, or HI) is contained in the atmosphere, an amorphous semiconductor film containing fluorine, chlorine, bromine, or iodine can be formed.

The buffer layer 54 is preferably formed using an amorphous semiconductor film which does not contain a crystal grain. Therefore, when the buffer layer 54 is formed by a high-frequency plasma CVD method with a frequency of several tens to several hundreds of megahertz or a microwave plasma CVD method, deposition conditions are preferably controlled so that an amorphous semiconductor film does not contain a crystal grain.

In a later process for forming source or drain regions, the buffer layer 54 is partially etched. At that time, it is preferable that the buffer layer 54 be formed with a sufficient thickness so that part thereof is left after etching, so as not to expose the microcrystalline semiconductor film 53. Typically, the buffer layer 54 is preferably formed with a thickness greater than or equal to 100 nm and less than or equal to 400 nm, more preferably greater than or equal to 200 and less than or equal to 300 nm. In a display device including a thin film transistor to which a high voltage (e.g., approximately 15 V) is applied, typically, in a liquid crystal display device, if the buffer layer 54 is formed to have a large thickness as shown in the above range, withstand voltage is increased, so that deterioration of the thin film transistor can be prevented even if high voltage is applied to the thin film transistor.

Note that an impurity imparting one conductivity type such as phosphorus or boron is not added to the buffer layer 54. The buffer layer 54 functions as a barrier layer so that an impurity imparting one conductivity type is not dispersed into the microcrystalline semiconductor film 53 from a semiconductor film 55 to which an impurity imparting one conductivity type is added. In the case where the buffer layer is not provided, if the microcrystalline semiconductor film 53 and the semiconductor film 55 to which an impurity imparting one conductivity type is added are in contact with each other, there is a concern that the impurity might be moved by an etching step or a heating treatment which will be performed later, which results in difficulty in controlling the threshold value.

Further, by forming the buffer layer 54 on the surface of the microcrystalline semiconductor film 53, natural oxidation of surfaces of crystal grains contained in the microcrystalline semiconductor film 53 can be prevented. In particular, in a region where an amorphous semiconductor is in contact with microcrystal grains, a crack is likely to be caused due to local stress. When this crack is exposed to oxygen, the crystal grains are oxidized, and silicon oxide is formed.

An energy gap of the buffer layer 54 that is an amorphous semiconductor film is larger than that of the microcrystalline semiconductor film 53 (an energy gap of the amorphous semiconductor film is greater than or equal to 1.6 eV and less than or equal to 1.8 eV, and an energy gap of the microcrystalline semiconductor film 53 is greater than or equal to 1.1 eV and less than or equal to 1.5 eV), has higher resistance, and has lower mobility, i.e., a fifth to a tenth of that of the microcrystalline semiconductor film 53. Therefore, in a thin film transistor which will be formed later, the buffer layer formed between source or drain regions and the microcrystalline semiconductor film 53 functions as a high-resistance region, and the microcrystalline semiconductor film 53 functions as a channel formation region. Accordingly, the off current of the thin film transistor can be reduced. When the thin film transistor is used as a switching element of a display device, the contrast of the display device can be improved.

It is preferable that the buffer layer 54 be formed over the microcrystalline semiconductor film 53 by a plasma CVD method, at a temperature of 300° C. to 400° C. By this deposition treatment, hydrogen is supplied to the microcrystalline semiconductor film 53, and the same effect as hydrogenation of the microcrystalline semiconductor film 53 can be obtained. In other words, by depositing the buffer layer 54 over the microcrystalline semiconductor film 53, hydrogen is dispersed into the microcrystalline semiconductor film 53, and dangling bonds can be terminated.

Next, after the buffer layer 54 is deposited, the substrate is transferred without being exposed to the atmosphere, and the semiconductor film 55 to which an impurity imparting one conductivity type is added is preferably deposited in a vacuum chamber which is different from the vacuum chamber for depositing the buffer layer 54. A cross-sectional view of this stage is shown in FIG. 9D. By depositing the semiconductor film 55 to which an impurity imparting one conductivity is added in a vacuum chamber which is different from the vacuum chamber for depositing the buffer layer 54, the impurity imparting one conductivity type can be prevented from being mixed into the buffer layer when the buffer layer is deposited.

In the case where an n-channel thin film transistor is formed, phosphorus may be added as a typical impurity element to the semiconductor film 55 to which an impurity imparting one conductivity type is added, and an impurity gas such as PH₃ may be added to silicon hydride. In the case where a p-channel thin film transistor is formed, boron may be added as a typical impurity element, and an impurity gas such as B₂H₆ may be added to silicon hydride. The semiconductor film 55 to which an impurity imparting one conductivity type is added can be formed using a microcrystalline semiconductor or an amorphous semiconductor. The semiconductor film 55 to which an impurity imparting one conductivity type is added is formed with a thickness greater than or equal to 2 nm and less than or equal to 50 nm. By reducing the thickness of the semiconductor film to which an impurity imparting one conductivity type is added, throughput can be improved.

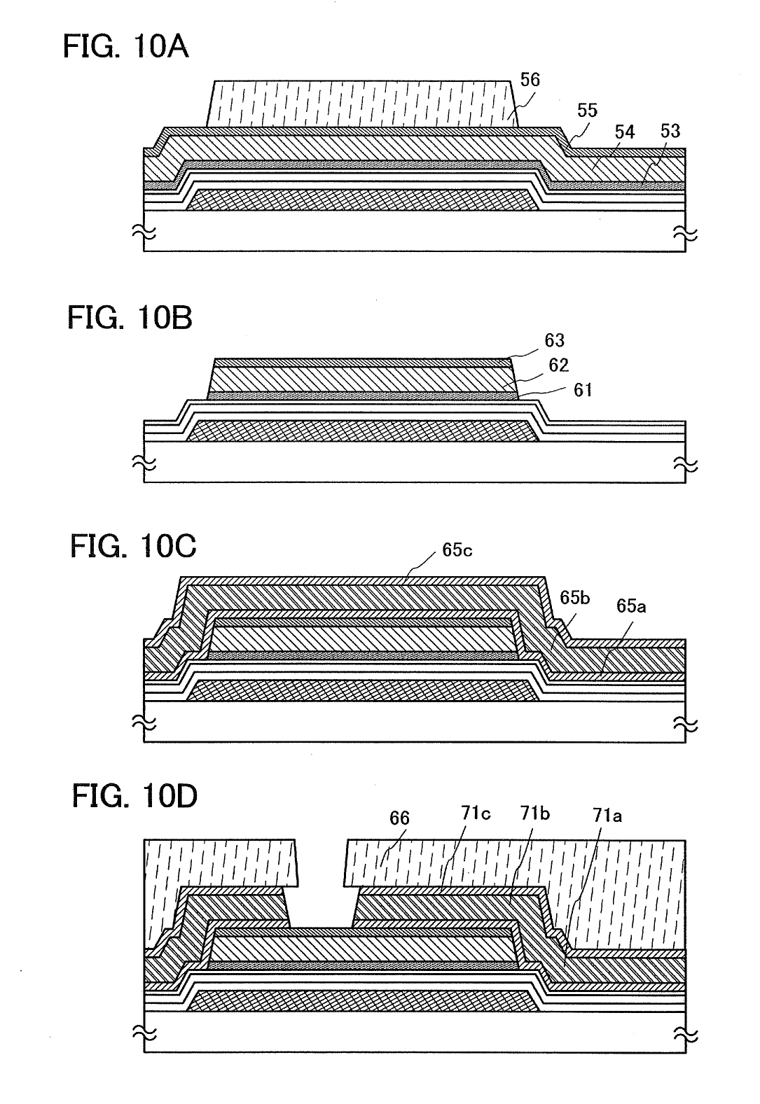

Then, as shown in FIG. 10A, a resist mask 56 is formed over the semiconductor film 55 to which an impurity element imparting one conductivity is added. The resist mask 56 is formed by a photolithography technique or an inkjet method. Here, with the use of a second photomask, the semiconductor film 55 to which an impurity imparting one conductivity type is added is coated with a resist. The resist is exposed to light and developed, whereby the resist mask 56 is formed.

Next, the microcrystalline semiconductor film 53, the buffer layer 54, and the semiconductor film 55 to which an impurity imparting one conductivity is added are etched and separated using the resist mask 56. As shown in FIG. 10B, a microcrystalline semiconductor film 61, a buffer layer 62, and a semiconductor film 63 to which an impurity imparting one conductivity type is added are formed. After that, the resist mask 56 is removed.

The side faces in the end portions of the microcrystalline semiconductor film 61 and the buffer layer 62 are inclined, so that leakage current can be prevented from flowing between the source or drain regions formed over the buffer layer 62 and the microcrystalline semiconductor film 61. In addition, leakage current between the source or drain electrodes and the microcrystalline semiconductor film 61 can be prevented. The inclination angle of the side faces in the end portions of the microcrystalline semiconductor film 61 and the buffer layer 62 is 30° to 90°, preferably 45° to 80°. By employing such an angle, disconnection of the source or drain electrode due to the step shape can be prevented.

Then, as shown in FIG. 10C, a conductive film 65a, a conductive film 65b, and a conductive film 65c are formed so as to cover the gate insulating film 52c and the semiconductor film 63 to which an impurity imparting one conductivity type is added. The conductive films 65a to 65c are preferably formed with a single layer or a stacked layer of aluminum or an aluminum alloy to which an element to improve heat resistance or an element to prevent a hillock, such as copper, silicon, titanium, neodymium, scandium, or molybdenum, is added. Alternatively, a film in contact with the semiconductor film to which an impurity element imparting one conductivity type is added may be formed of titanium, tantalum, molybdenum, or tungsten, or nitride of such an element, and aluminum or an aluminum alloy may be formed thereover to form a stacked-layer structure. Further alternatively, top and bottom surfaces of aluminum or an aluminum alloy may be each covered with titanium, tantalum, molybdenum, tungsten, or nitride of such an element to form a stacked-layer structure. Here, as the conductive film, a conductive film with a three-layer structure where the conductive films 65a to 65c are stacked is described. A stacked-layer conductive film where molybdenum films are used as the conductive films 65a and 65c and an aluminum film is used as the conductive film 65b or a stacked-layer conductive film where titanium films are used as the conductive films 65a and 65c and an aluminum film is used as the conductive film 65b can be given. The conductive films 65a to 65c are formed by a sputtering method or a vacuum evaporation method.

Next, as shown in FIG. 10D, a resist mask 66 is formed over the conductive films 65a to 65c using a third photomask, and the conductive films 65a to 65c are partially etched to form pairs of source or drain electrodes 71a, source or drain electrodes 71b, and source or drain electrodes 71c. By performing wet etching on the conductive films 65a to 65c, the conductive films 65a to 65c are selectively etched. Consequently, since the conductive films 65a to 65c are isotropically etched, the source or drain electrodes 71a to 71c which each have a smaller area than the resist mask 66 can be formed.

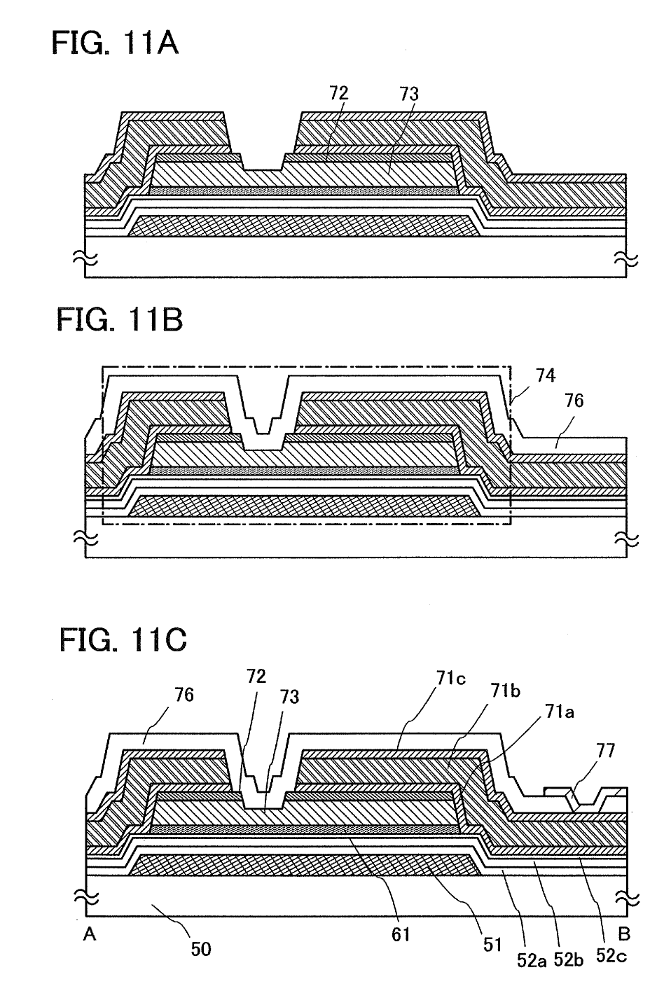

Next, as shown in FIG. 11A, the semiconductor film 63 to which an impurity imparting one conductivity type is added is etched using the resist mask 66 to form a pair of source or drain regions 72. In this etching step, part of the buffer layer 62 is also etched. The buffer layer which is etched partially and has a recessed portion (a groove) is referred to as a buffer layer 73. The source or drain regions and the recessed portion (the groove) of the buffer layer can be formed in the same step. By making a depth of the recessed portion (the groove) of the buffer layer to be half to one third of a thickness of the thickest region of the buffer layer 73, it is possible to have distance between the source or drain regions; therefore, leakage current between the source or drain regions can be reduced. After that, the resist mask 66 is removed.

The quality of the resist mask is changed when the resist mask is exposed to plasma used for, in particular, dry-etching or the like and the resist mask is not completely removed in the resist removal step; thus, the buffer layer 73 is etched by approximately 50 nm to prevent a residue from being left behind. The resist mask 66 is used twice for the partial etching treatment of the conductive films 65a to 65c and for the etching treatment at the time of forming the source or drain regions 72, and a residue thereof tends to remain if dry-etching is employed for each treatment. Therefore, it is effective to form the buffer layer 73, which may be etched when the residue is being removed completely, to be thick. In addition, the buffer layer 73 can prevent plasma damage to the microcrystalline semiconductor film 61 during dry etching.

Then, as shown in FIG. 11B, an insulating film 76 which covers the source or drain electrodes 71a to 71c, the source or drain regions 72, the buffer layer 73, the microcrystalline semiconductor film 61, and the gate insulating film 52c is formed. The insulating film 76 can be formed by using the same deposition method as the gate insulating films 52a, 52b, and 52c. Note that the insulating film 76 is formed to prevent intrusion of a contamination impurity such as an organic matter, a metal, or water vapor included in the air; thus, a dense film is preferably used for the insulating film 76. Further, by using a silicon nitride film as the insulating film 76, the oxygen concentration in the buffer layer 73 can be less than or equal to 5×10¹⁹ atoms/cm³, preferably less than or equal to 1×10¹⁹ atoms/cm³.

As shown in FIG. 11B, with such a shape in which the end portions of the source or drain electrodes 71a to 71c and the end portions of the source or drain regions 72 are not aligned, the end portions of the source or drain electrodes 71a to 71c are apart from each other; therefore, leakage current and a short circuit between the source or drain electrodes can be prevented. Furthermore, because the end portions of the source or drain electrodes 71a to 71c are deviated from those of the source or drain regions 72, an electric field is not concentrated on the end portions of the source or drain electrodes 71a to 71c and the source or drain regions 72; thus, leakage current between the gate electrode 51 and the source or drain electrodes 71a to 71c can be prevented. Therefore, a thin film transistor with high reliability and high withstand voltage can be manufactured.

Through the steps described above, a thin film transistor 74 can be formed.

In the thin film transistor described in this embodiment mode, the gate insulating film, the microcrystalline semiconductor film, the buffer layer, the source or drain regions, and the source or drain electrodes are stacked over the gate electrode, and the buffer layer covers the surface of the microcrystalline semiconductor film which functions as a channel formation region. In addition, a recessed portion (a groove) is formed in part of the buffer layer, and regions other than the recessed portion are covered with the source or drain regions. In other words, due to the recessed portion formed in the buffer layer, the source or drain regions are apart from each other; thus, leakage current between the source or drain regions can be reduced. In addition, because the recessed portion is formed by etching part of the buffer layer, an etching residue which is generated in the step of forming the source or drain regions can be removed. Accordingly, leakage current (parasitic channel) can be prevented from being generated between the source or drain regions through the residue.

The buffer layer is formed between the microcrystalline semiconductor film which functions as a channel formation region and the source or drain regions. In addition, the buffer layer covers the surface of the microcrystalline semiconductor film. Because the buffer layer, which has high resistance, is formed also between the microcrystalline semiconductor film and the source or drain regions, occurrence of a leakage current can be reduced in a thin film transistor, and deterioration due to application of high voltage can be suppressed. In addition, the buffer layer, the microcrystalline semiconductor film, and the source or drain regions are formed in regions that overlap with the gate electrode. Thus, the structure of the buffer layer is not affected by the shape of the end portion of the gate electrode. In the case where the gate electrode is formed with a stacked-layer structure, if aluminum is used for a lower layer thereof, there is a concern that aluminum might be exposed to the side face of the gate electrode, which may cause a hillock. However, by forming the source or drain regions so as not to overlap with the end portion of the gate electrode, a short circuit in the region which overlaps with the side face of the gate electrode can be prevented. Moreover, because the amorphous semiconductor film, the surface of which is terminated with hydrogen, is formed as the buffer layer on the surface of the microcrystalline semiconductor film, the microcrystalline semiconductor film can be prevented from being oxidized, and an etching residue which is generated in the step of forming the source or drain regions can be prevented from being mixed into the microcrystalline semiconductor film. Therefore, the thin film transistor can have excellent electric characteristics and excellent resistance to voltage.

Further, a channel length of the thin film transistor can be shortened, and a planar area of the thin film transistor can be reduced.

Next, a contact hole is formed in the insulating film 76 by partially etching the insulating film 76 using a resist mask formed using a fourth photomask. Then, a pixel electrode 77 which is in contact with the source or drain electrode 71c in the contact hole is formed. Note that FIG. 11C corresponds to a cross-sectional view taken along chain line A-B in FIG. 12.

As shown in FIG. 12, it can be seen that the end portions of the source or drain regions 72 are positioned outside of the end portions of the source or drain electrodes 71c. Further, the end portions of the buffer layer 73 are positioned outside of the end portions of the source or drain electrodes 71c and the end portions of the source or drain regions 72. Furthermore, one of the source or drain electrodes has a shape in which one electrode partially surrounds the other of the source or drain regions (specifically, a U shape or a C shape). Therefore, an area in which carriers move can be increased, and thus the amount of current can be increased and an area for a thin film transistor can be reduced. Further, unevenness of the gate electrode has little influence because the microcrystalline semiconductor film and the source or drain electrodes overlap with each other over the gate electrode, so that reduction in coverage and generation of leakage current can be suppressed. Note that one of the source or drain electrodes also functions as a source or drain wiring.

In addition, the width of a side portion of a gate wiring which does not overlap with the microcrystalline semiconductor film is smaller than the width of a side portion of the gate electrode which overlaps with the microcrystalline semiconductor film. Accordingly, improvement in aperture ratio of the pixel portion is achieved. In addition, an angle (a taper angle) of the side face of the gate electrode which overlaps with the microcrystalline semiconductor film is smaller than an angle (a taper angle) of the side face of the gate wiring which does not overlap with the microcrystalline semiconductor film. Accordingly, coverage of a film which is formed above is made favorable.

In addition, the pixel electrode 77 can be formed of a light-transmitting conductive material such as indium oxide containing tungsten oxide, indium zinc oxide containing tungsten oxide, indium oxide containing titanium oxide, indium tin oxide containing titanium oxide, indium tin oxide, indium zinc oxide, or indium tin oxide to which silicon oxide is added.

Further, a conductive composition containing a conductive macromolecule (also referred to as a conductive polymer) can be used for the pixel electrode 77. The pixel electrode 77 formed of the conductive composition preferably has a sheet resistance which is less than or equal to 10000 ohm/square and a light transmittance which is greater than or equal to 70% at a wavelength of 550 nm. Further, the resistance of the conductive macromolecule included in the conductive composition is preferably less than or equal to 0.1 Ω·cm.

As the conductive macromolecule, a so-called π-electron conjugated conductive macromolecule can be used. As examples thereof, polyaniline or a derivative thereof, polypyrrole or a derivative thereof, polythiophene or a derivative thereof, a copolymer of two or more kinds of these materials, and the like can be given.

Here, as the pixel electrode 77, a film of indium tin oxide is formed by a sputtering method, and then the indium tin oxide film is coated with a resist. Subsequently, the resist is exposed to light and developed using a fifth photomask to form a resist mask. Then, the pixel electrode 77 is formed by etching the indium tin oxide film using the resist mask.

Through the above process, an element substrate which can be used for a display device can be formed.

This embodiment mode can be freely combined with Embodiment Mode 1, 2, 3, 4, or 5.

### Embodiment Mode 7

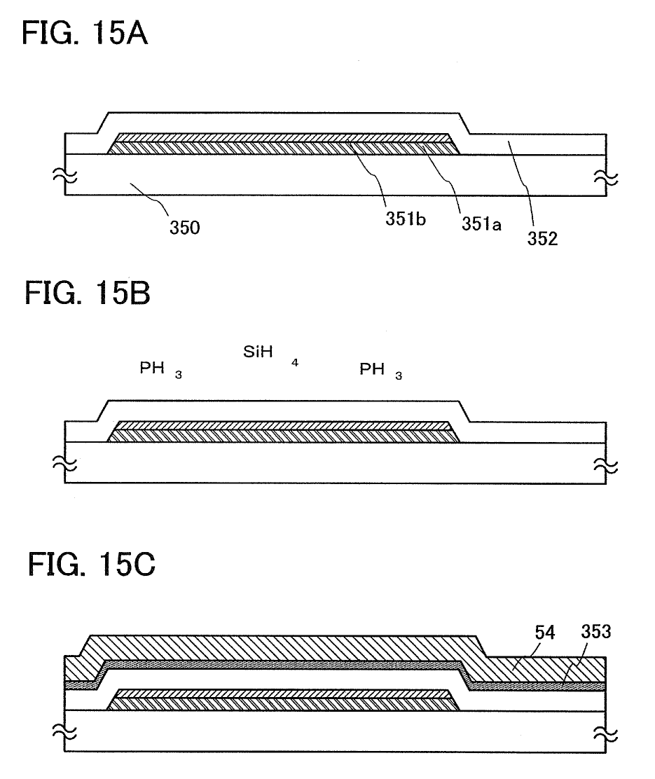

In this embodiment mode, an example is shown in which, before the substrate is transferred to a vacuum chamber, hydrogen, a silane gas, and a slight amount of a phosphine (PH₃) gas are introduced after a gas (an atmospheric component such as oxygen and nitrogen, or an etching gas used in cleaning the vacuum chamber) that is attached to the inner wall of the vacuum chamber is removed by generating plasma by introducing hydrogen or a rare gas. Since only part of steps in this embodiment mode are different from steps in Embodiment Mode 2, only different steps will be described in detail below with reference to FIGS. 15A to 15C. Portions which are the same as those of Embodiment Mode 2 in FIGS. 15A to 15C are denoted by the same reference numerals.

First, a gate electrode is formed over a substrate 350 using a multi-tone mask in a manner similar to that of Embodiment Mode 6. Here, a non-alkaline glass substrate the size of which is 600 mm×720 mm is used. Since an example where a display device with a large display screen is manufactured using a large area substrate is described here, a gate electrode is formed by stacking a first conductive layer 351a formed of aluminum having low electric resistance and a second conductive layer 351b with heat resistance higher than that of the first conductive layer 351a. As an etching apparatus, the ECCP mode etching apparatus shown in FIG. 14 is used.

Next, a gate insulating film 352 is formed over the second conductive layer 351b which is the upper layer of the gate electrode. It is preferable that the insulating film 352 be only a single layer of a silicon nitride film in the case where a thin film transistor is used for a switching element of a liquid crystal display device, in which AC driving is performed. Here, the single silicon nitride film (dielectric constant: 7.0, thickness: 300 nm) is formed by a plasma CVD method as the gate insulating film 352. A cross-sectional view up through these steps is shown in FIG. 15A.

Then, after the gate insulating film is deposited, the substrate is transferred without being exposed to the atmosphere, and a microcrystalline semiconductor film is deposited in a vacuum chamber which is different from a vacuum chamber for depositing the gate insulating film.

Before the substrate is transferred to a vacuum chamber of a deposition apparatus, hydrogen, a silane gas, and a slight amount of a phosphine (PH₃) gas are introduced after a gas (an atmospheric component such as oxygen and nitrogen, or an etching gas used in cleaning the vacuum chamber) that is attached to the inner wall of the vacuum chamber is removed by generating plasma by introducing hydrogen or a rare gas. The silane gas can be reacted with oxygen, moisture, or the like in the vacuum chamber. The slight amount of a phosphine gas can make phosphorus be contained in a microcrystalline semiconductor film which will be deposited later.

Subsequently, the substrate is transferred to the vacuum chamber and is exposed to the silane gas and the slight amount of a phosphine gas, as shown in FIG. 15B. After that, a microcrystalline semiconductor film is formed. The microcrystalline semiconductor film can be typically formed by generating plasma by diluting a silicon hydride such as SiH₄ or Si₂H₆ with hydrogen. With the use of hydrogen at a flow rate greater than 100 times and less than or equal to 2000 times as high as than that of a silane gas, a microcrystalline semiconductor film 353 containing phosphorus or hydrogen can be formed. By exposure to the slight amount of a phosphine gas, the microcrystalline semiconductor film 353 is formed by promoting generation of crystal nuclei. This crystalline semiconductor film 353 shows a concentration profile in which the concentration of phosphorus decreases as a distance from the interface of the gate insulating film increases.

Next, a buffer layer 54 formed of amorphous silicon containing hydrogen is stacked using hydrogen with a flow rate greater than or equal to 1 times and less than or equal to 10 times as high as that of silicon hydride, preferably with a flow rate greater than or equal to 1 times and less than or equal to 5 times as high as that of silicon hydride by changing a deposition condition in the same chamber. A cross-sectional view up through these steps is shown in FIG. 15C.

Then, after the buffer layer 54 is deposited, the substrate is transferred without being exposed to the atmosphere, and a semiconductor film 55 to which an impurity imparting one conductivity type is added is deposited in a vacuum chamber which is different from the vacuum chamber for depositing the microcrystalline semiconductor film 353 and the buffer layer 54. Since the subsequent steps after deposition of the semiconductor film 55 are the same as those in Embodiment Mode 6, the detailed descriptions are omitted here.

This embodiment mode can be freely combined with Embodiment Mode 1, 2, 3, 4, 5, or 6.

### Embodiment Mode 8

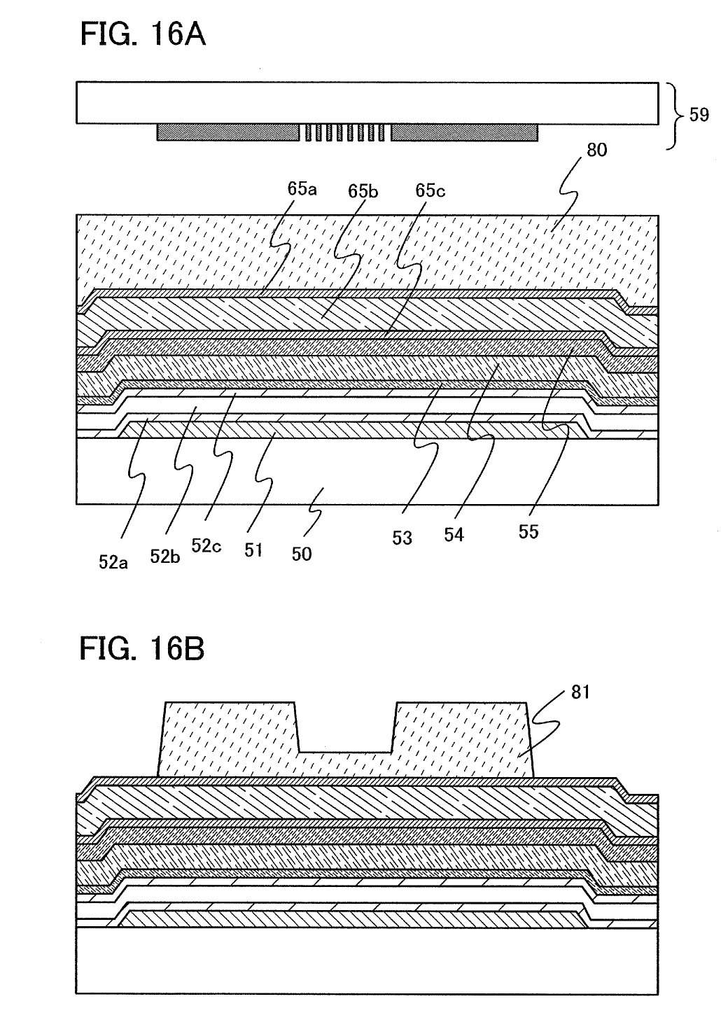

Another method for forming a thin film transistor, which is different from that of Embodiment Mode 2, will be described with reference to FIGS. 16A and 16B, FIGS. 17A to 17C, and FIGS. 18A and 18B. Here, a process for manufacturing a thin film transistor, which uses a process capable of reducing the number of photomasks as compared to Embodiment Mode 1 described above, will be described.

In a manner similar to FIG. 9A shown in Embodiment Mode 6, the conductive film is formed over the substrate 50, the conductive film is coated with a resist, and the conductive film is partially etched using a resist mask which is formed in a photolithography step using a multi-tone mask, so as to form a gate electrode 51. Although not shown, a gate electrode or a gate wiring having side faces each with a different taper angle is formed as appropriate. Next, the gate insulating films 52a, 52b, and 52c are formed in this order over the gate electrode 51.

Then, the crystalline semiconductor film 53 is formed under the first deposition condition. Subsequently, in a manner similar to that of FIG. 9C shown in Embodiment Mode 6, the microcrystalline semiconductor film 53 is formed in the same chamber under the second deposition condition. Next, in a manner similar to that of FIG. 9D shown in Embodiment Mode 6, the buffer layer 54 and the semiconductor film 55 to which an impurity imparting one conductivity type is added are formed in this order over the microcrystalline semiconductor film 53.

Then, a conductive film 65a, a conductive film 65b, and a conductive film 65c are formed over the semiconductor film 55 to which an impurity imparting one conductivity type is added. Next, as shown in FIG. 16A, the conductive film 65a is coated with a resist 80.

The resist 80 can be a positive type resist or a negative type resist. Here, a positive resist is used.

Then, the resist 80 is irradiated with light using a multi-tone mask 59 as a second photomask to expose the resist 80 to light.

After the light exposure using the multi-tone mask is performed, a resist mask 81 having regions with different thicknesses can be formed, as shown in FIG. 16B.

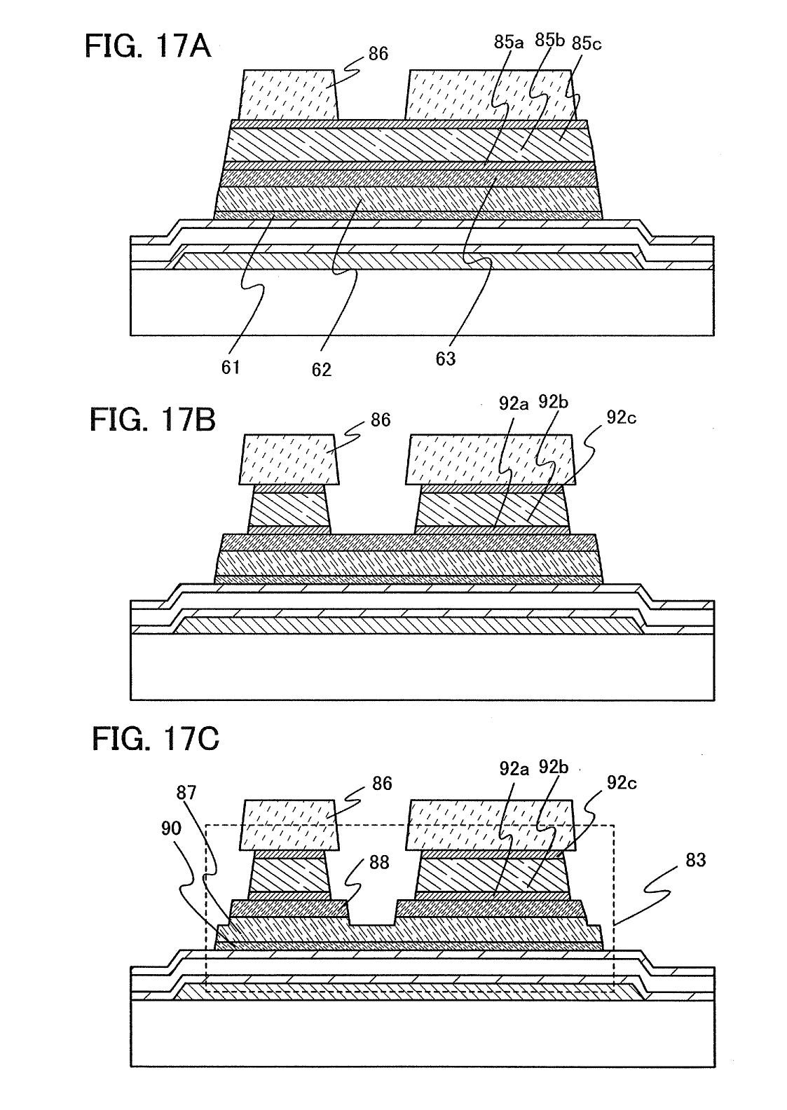

Next, with the resist mask 81 as a mask, the microcrystalline semiconductor film 53, the buffer layer 54, the semiconductor film 55 to which an impurity imparting one conductivity type is added, and the conductive films 65a to 65c are etched to be separated. Consequently, a microcrystalline semiconductor film 61, a buffer layer 62, a semiconductor film 63 to which an impurity imparting one conductivity type is added, and a conductive film 85a, a conductive film 85b, and a conductive film 85c as shown in FIG. 17A can be formed.

Then, ashing is performed on the resist mask 81. Consequently, the areas and the thicknesses of the resist mask are reduced. At this time, the resist in a region with a small thickness (a region overlapping with part of the gate electrode 51) is removed to form separated resist masks 86 as shown in FIG. 17A.

Next, the conductive films 85a to 85c are etched to be separated using the resist masks 86. Consequently, pairs of source or drain electrodes 92a, source or drain electrodes 92b, and source or drain electrodes 92c can be formed as shown in FIG. 17B. By wet etching of the conductive films 85a to 85c with use of the resist masks 86, the end portions of the conductive films 85a to 85c are selectively etched. Consequently, source or drain electrodes 92a, source or drain electrodes 92b, and source or drain electrodes 92c having smaller areas than the resist masks 86 can be formed.

Then, the semiconductor film 63 to which an impurity imparting one conductivity type is added is etched using the resist masks 86 to form a pair of source or drain regions 88. In this etching process, part of the buffer layer 62 is also etched. The partially etched buffer layer is referred to as a buffer layer 87. In the buffer layer 87, a depression is formed. The source or drain regions and the recessed portion (the groove) of the buffer layer can be formed in the same step. Here, the buffer layer 87 is partially etched using the resist masks 86 having smaller areas than that of the resist mask 81, so that end portions of the buffer layer 87 are located outer side than those of the source or drain regions 88. After that, the resist mask 86 is removed. In addition, the end portions of the source or drain electrodes 92a to 92c are not aligned with the end portions of the source or drain regions 88, and the end portions of the source or drain regions 88 are formed outside the end portions of the source or drain electrodes 92a to 92c.

As shown in FIG. 17C, with such a shape in which the end portions of the source or drain electrodes 92a to 92c and the end portions of the source or drain regions 88 are not aligned, the end portions of the source or drain electrodes 92a to 92c are apart from each other; therefore, leakage current and a short circuit between the source or drain electrodes can be prevented. Furthermore, because the end portions of the source or drain electrodes 92a to 92c are deviated from those of the source or drain regions 88, an electric field is not concentrated on the end portions of the source or drain electrodes 92a to 92c and the source or drain regions 88; thus, leakage current between the gate electrode 51 and the source or drain electrodes 92a to 92c can be prevented.

Through the steps described above, a thin film transistor 83 can be formed. In addition, the thin film transistor can be formed using two photomasks.

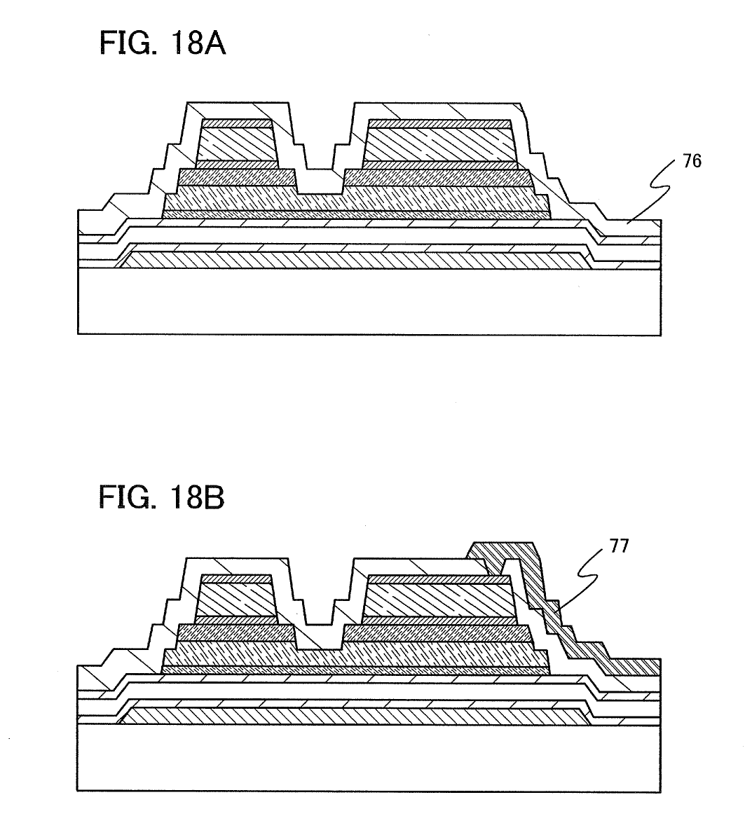

Next, as shown in FIG. 18A, an insulating film 76 is formed over the source or drain electrodes 92a to 92c, the source or drain regions 88, the buffer layer 87, a microcrystalline semiconductor film 90, and the gate insulating film 52c.

Then, a contact hole is formed by partially etching the insulating film 76 using a resist mask formed using a third photomask. In the contact hole, a pixel electrode 77 in contact with the source or drain electrode 92c is formed. Here, as the pixel electrode 77, an indium tin oxide film is formed by a sputtering method, and then the indium tin oxide film is coated with a resist. Then, the resist is exposed to light and developed using a fourth photomask to form a resist mask. Subsequently, the pixel electrode 77 is formed by etching the indium tin oxide film using the resist mask.

Through the above process, an element substrate which can be used for a display device can be formed in which a multi-tone mask is used to reduce the number of masks.

This embodiment mode can be freely combined with Embodiment Mode 1, 2, 3, 4, 5, 6, or 7.

### Embodiment Mode 9

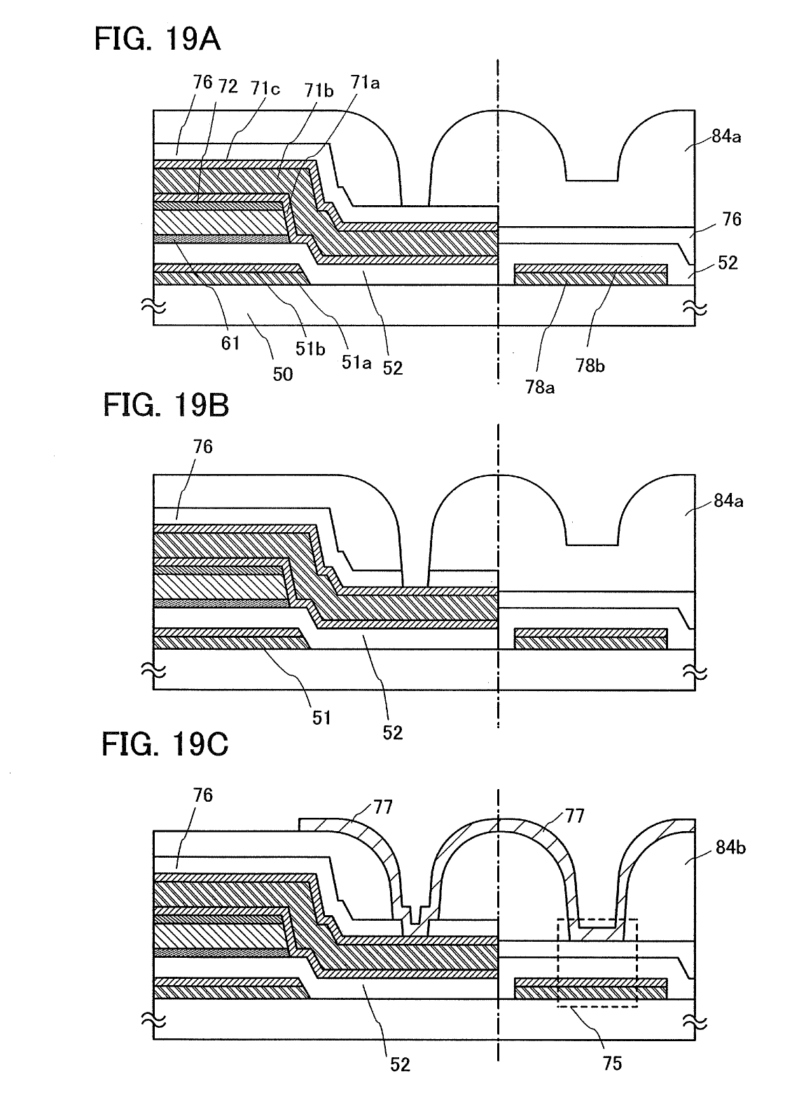

In this embodiment mode, a step of forming a storage capacitor by using a multi-tone mask and a step of forming a contact between a thin film transistor and a pixel electrode will be described. Note that portions which are the same as those of Embodiment Mode 6 in FIGS. 19A to 19C are denoted by the same reference numerals.

After the steps up to and including the step of forming the insulating film 76 in accordance with Embodiment Mode 6, a first interlayer insulating film 84a having openings with different depths is formed by using a multi-tone mask. Here, an angle of a side face of a capacitor wiring which serves as a capacitor portion is wider than an angle of a side face of the gate electrode, as shown in FIG. 19A. An aperture ratio of a pixel portion is improved by making angles of the side faces of the wiring different by a multi-tone mask so as to control the wiring width in each place. A cross-sectional view at this stage corresponds to FIG. 19A.

As shown in FIG. 19A, a first opening which exposes the surface of the insulating film 76 is provided above the source or drain electrode 71c and a second opening which is at a shallower depth than the first opening is provided over a capacitor wiring formed of a stacked layer of a first conductive layer 78a and a second conductive layer 78b. Note that the first conductive layer 78a and the second conductive layer 78b of the capacitor wiring are formed in the same steps as a first conductive layer 51a and a second conductive layer 51b of the gate electrode, respectively.

Next, part of the insulating film 76 is selectively etched using the first interlayer insulating film 84a as a mask to partially expose the source or drain electrode 71c.

Then, ashing is performed on the first interlayer insulating film 84a until the second opening is enlarged to expose the surface of the insulating film 76. Although the first opening is enlarged at the same time, the size of the opening formed in the insulating film 76 is not changed. Thus, a step is formed.

Subsequently, a pixel electrode 77 is formed. A cross-sectional view at this stage corresponds to FIG. 19C. The first interlayer insulating film is reduced to have the size of a second interlayer insulating film 84b by ashing. Further, as for a storage capacitor 75, the insulating film 76 and the gate insulating film 52 are used as dielectric substances and the capacitor wiring and the pixel electrode 77 are used as a pair of electrodes.

In this manner, the storage capacitor can be formed with a small number of steps by using a multi-tone mask.

This embodiment mode can be freely combined with Embodiment Mode 1, 2, 3, 4, 5, 6, 7, or 8.

### Embodiment Mode 10

In this embodiment mode, a liquid crystal display device having a thin film transistor described in Embodiment Mode 6, as one mode of a display device, will be described below.

First, a vertical alignment (VA) liquid crystal display device is described. The VA liquid crystal display device is a kind of form in which alignment of liquid crystal molecules of a liquid crystal panel is controlled. The VA liquid crystal display device is a form in which liquid crystal molecules are vertical to a panel surface when voltage is not applied. In this embodiment mode, it is devised to particularly separate pixels into some regions (sub-pixels) so that molecules are aligned in different directions in the respective regions. This is referred to as multi-domain or multi-domain design. In the following description, a liquid crystal display device with multi-domain design is described.

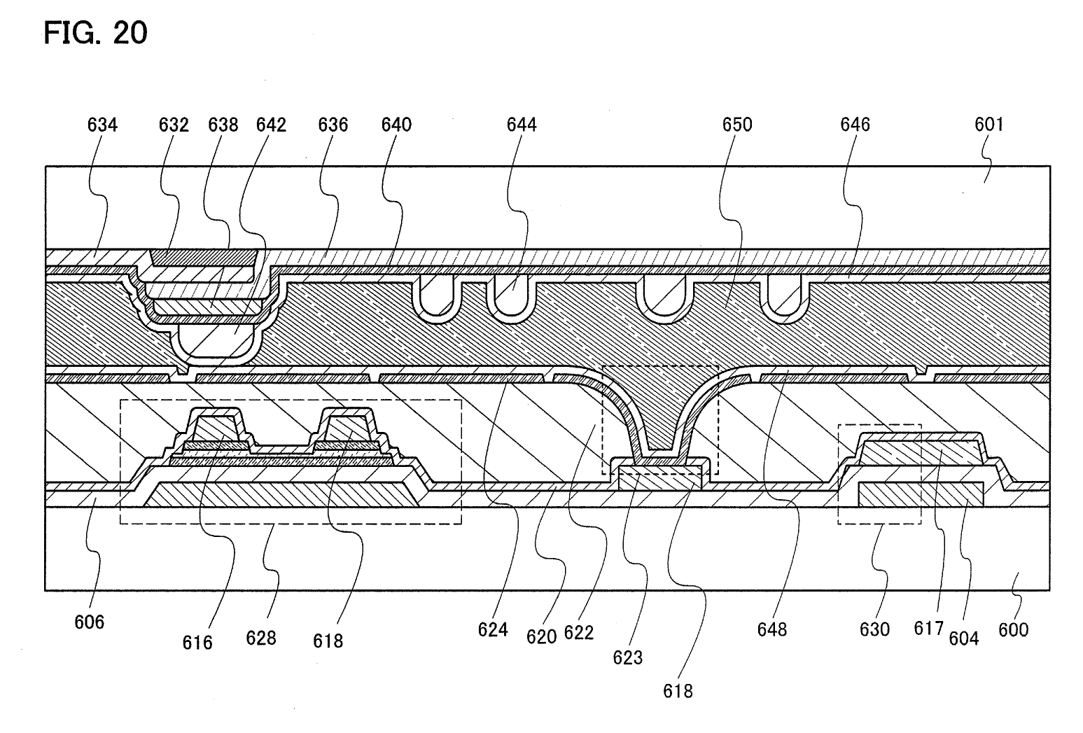

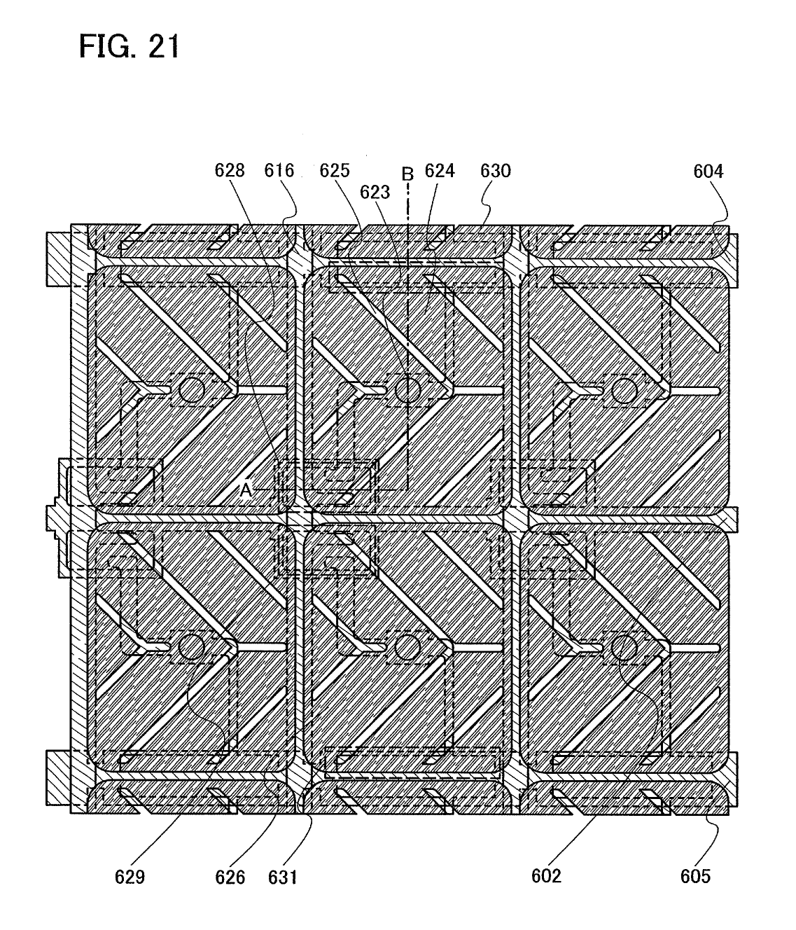

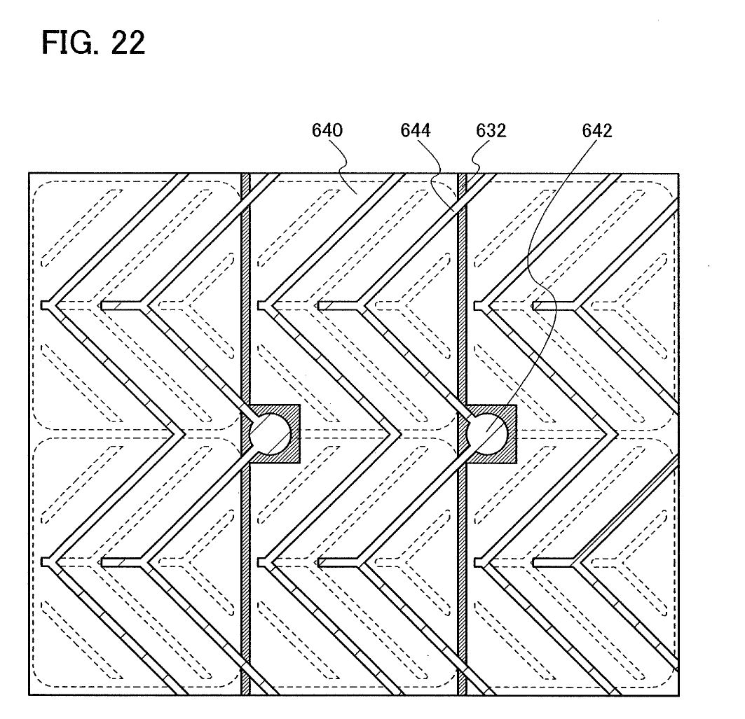

FIG. 21 and FIG. 22 show a pixel electrode and a counter electrode, respectively. FIG. 21 is a plan view of a side of a substrate on which the pixel electrode is formed. FIG. 20 shows a cross-sectional structure taken along line A-B in FIG. 21. FIG. 22 is a plan view of a side of a substrate on which the counter electrode is formed. The following description is made with reference to these drawings.

In FIG. 20, a substrate 600 over which a TFT 628, a pixel electrode 624 connected to the TFT 628, and a storage capacitor portion 630 are formed and a counter substrate 601 for which a counter electrode 640 and the like are provided are overlapped with each other, and liquid crystals are injected between the substrate 600 and the counter substrate 601.

At the position where the counter substrate 601 is provided with a spacer 642, a light-shielding film 632, a first coloring film 634, a second coloring film 636, a third coloring film 638, and the counter electrode 640 are formed. With this structure, the height of a projection 644 for controlling orientation of liquid crystals is made different from that of the spacer 642. An orientation film 648 is formed over the pixel electrode 624, and the counter electrode 640 is similarly provided with an orientation film 646. A liquid crystal layer 650 is formed between the orientation films 648 and 646.

Although a columnar spacer is used for the spacer 642 here, a bead spacer may be dispersed. Further, the spacer 642 may be formed over the pixel electrode 624 provided over the substrate 600.

The TFT 628, the pixel electrode 624 connected to the TFT 628, and the storage capacitor portion 630 are formed over the substrate 600. The pixel electrode 624 is connected to a wiring 618 via a contact hole 623 which penetrates an insulating film 620 which covers the TFT 628, the wiring, and the storage capacitor portion 630 and also penetrates a third insulating film 622 which covers the insulating film. In addition, the wiring 618 and a source or drain electrode of the TFT 628 are selectively etched using a multi-tone mask, and an angle of the side face of the wiring 618 is made wider than an angle of the side face of the source or drain electrode of the TFT 628, which contributes to improvement in aperture ratio. As the TFT 628, the thin film transistor shown in Embodiment Mode 6 can be used as appropriate. The storage capacitor portion 630 includes a first capacitor wiring 604 which is formed with the same multi-tone mask as a gate wiring 602 of the TFT 628 in accordance with Embodiment Mode 2, a gate insulating film 606, and a second capacitor wiring 617 which is formed in a manner similar to that of a wiring 616 and the wiring 618. In addition, an angle of the side face of the first capacitor wiring 604 is made wider than angles of the side faces of the wirings 616 and 618 of the TFT 628, which contributes to improvement in aperture ratio.

The pixel electrode 624, the liquid crystal layer 650, and the counter electrode 640 overlap with each other, so that a liquid crystal element is formed.

FIG. 21 shows a structure of the substrate 600 side. The pixel electrode 624 is formed using the material described in Embodiment Mode 6. The pixel electrode 624 is provided with a slit 625. The slit 625 is provided to control orientation of liquid crystals.

A TFT 629, a pixel electrode 626 connected to the TFT 629, and a storage capacitor portion 631, which are shown in FIG. 21, can be formed in a manner similar to that of the TFT 628, the pixel electrode 624, and the storage capacitor portion 630, respectively. Both the TFTs 628 and 629 are connected to the wiring 616. Each pixel of this liquid crystal panel includes the pixel electrodes 624 and 626. Each of the pixel electrodes 624 and 626 are a sub-pixel.

FIG. 22 shows a structure of a counter substrate side. The counter electrode 640 is formed over the light-shielding film 632. The counter electrode 640 is preferably formed using a material similar to that of the pixel electrode 624. The projection 644 that controls orientation of liquid crystals is formed over the counter electrode 640. Moreover, the spacer 642 is formed corresponding to the position of the light-shielding film 632.

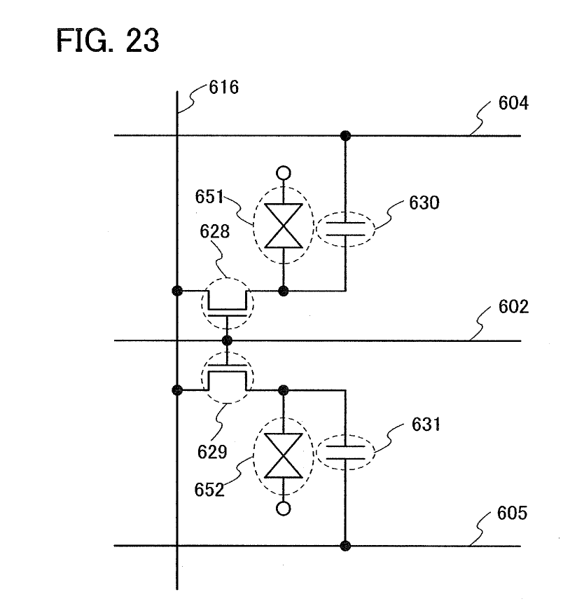

FIG. 23 shows an equivalent circuit of this pixel structure. Both the TFTs 628 and 629 are connected to the gate wiring 602 and the wiring 616. In this case, when potentials of the first capacitor wiring 604 and a third capacitor wiring 605 are different from each other, operations of a liquid crystal element 651 and a liquid crystal element 652 can vary. In other words, each potential of the first capacitor wiring 604 and the third capacitor wiring 605 is individually controlled, whereby orientation of liquid crystals is precisely controlled to expand a viewing angle.

When a voltage is applied to the pixel electrode 624 provided with the slit 625, distortion of an electric field (an oblique electric field) is generated in the vicinity of the slit 625. This slit 625 is disposed so as to alternately mesh with the projection 644 on the side of the counter substrate 601 and an oblique electric field is generated effectively to control orientation of liquid crystals, whereby the direction in which liquid crystals are oriented is made different depending on a place. In other words, a viewing angle of a liquid crystal panel is expanded by multi-domain.

Although an example of the VA liquid crystal display device is shown in the above description, the present invention is not particularly limited to the pixel electrode structure shown in FIG. 21.

Next, a mode of a TN liquid crystal display device is described.

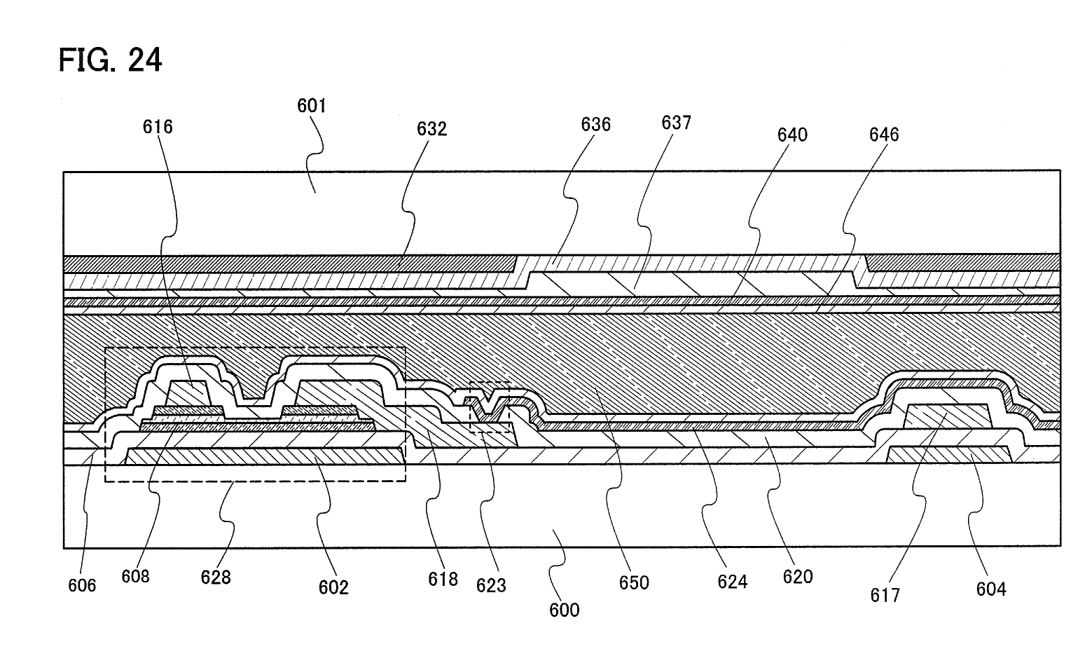

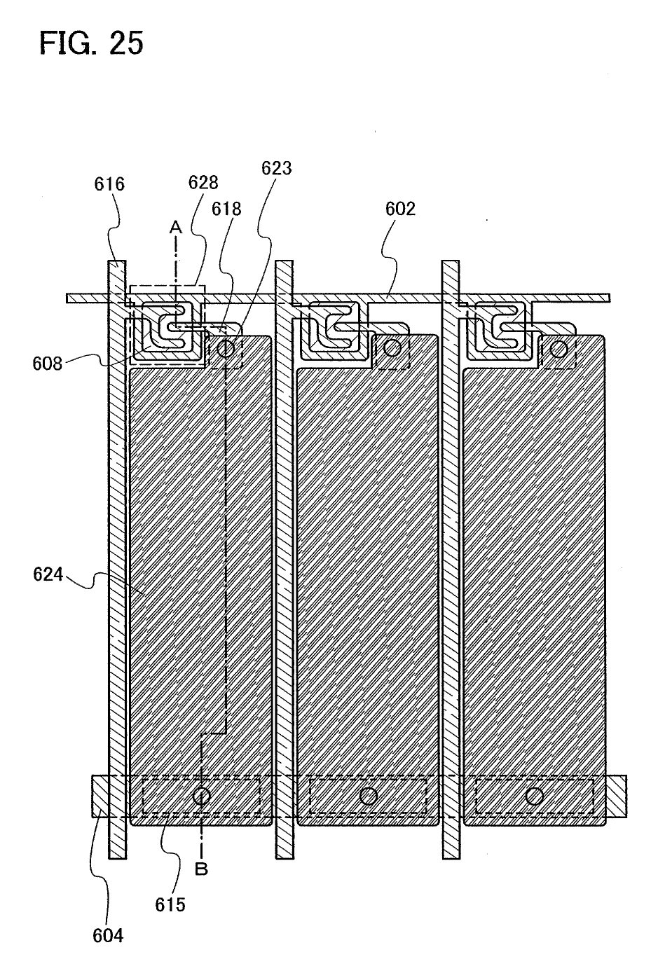

FIG. 24 and FIG. 25 show a pixel structure of a TN liquid crystal display device. FIG. 25 is a plan view. FIG. 24 shows a cross-sectional structure taken along line K-L in FIG. 25. The following description is made with reference to both of the figures. Note that in FIG. 24 and FIG. 25, portions which are the same as those in FIG. 20 are denoted by the same reference numerals.

A pixel electrode 624 is connected to a TFT 628 by a wiring 618 through a contact hole 623. A wiring 616 which functions as a data line is connected to the TFT 628. As the TFT 628, the TFT described in Embodiment Mode 2 can be used.

The pixel electrode 624 is formed using the pixel electrode 77 described in Embodiment Mode 2.

A counter substrate 601 is provided with a light-shielding film 632, a second coloring film 636, and a counter electrode 640. Moreover, a planarization film 637 is formed between the second coloring film 636 and the counter electrode 640 to prevent alignment disorder of the liquid crystal. A liquid crystal layer 650 is formed between the pixel electrode 624 and the counter electrode 640.

The pixel electrode 624, the liquid crystal layer 650, and the counter electrode 640 overlap with each other, so that a liquid crystal element is formed.

A substrate 600 or the counter substrate 601 may be provided with a color filter, a shielding film (a black matrix) for preventing disclination, or the like. Further, a polarizing plate is attached to a surface of the substrate 600, which is opposite to a surface on which the thin film transistor is formed. Moreover, a polarizing plate is attached to a surface of the counter substrate 601, which is opposite to a surface on which the counter electrode 640 is formed.

Through the steps described above, a liquid crystal display device can be manufactured. The liquid crystal display device in this embodiment mode has high contrast and high visibility because a thin film transistor with little off current, excellent electric characteristics, and high reliability is used in the liquid crystal display device. In addition, a liquid crystal display device having a high aperture ratio is realized by adjusting an angle of a side face of a wiring in each place with the use of a multi-tone mask. Moreover, by adjusting an angle of a side face of a wiring in each place with the use of a multi-tone mask, disconnection or short-circuit failure above the end portion of the wiring is reduced.

The present invention can also be applied to a horizontal electric field-mode liquid crystal display device. The horizontal electric-field mode is a method in which an electric field is applied to liquid crystal molecules in a cell in a horizontal direction, whereby liquid crystals are driven to express gray scales. In accordance with this mode, a viewing angle can be expanded up to approximately 180°.

This embodiment mode can be freely combined with Embodiment Mode 1, 2, 3, 4, 5, 6, 7, 8, or 9.

### Embodiment Mode 11

A structure of a display panel, which is one mode of a liquid crystal display device of the present invention, will be described below.

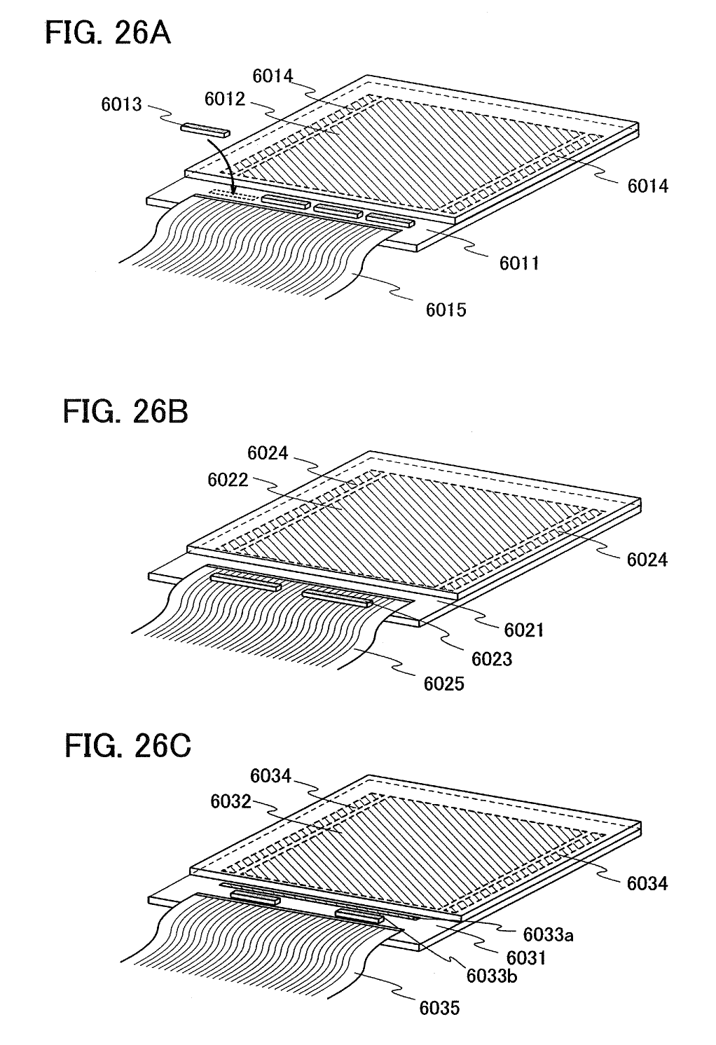

FIG. 26A shows a mode of a display panel in which a pixel portion 6012 formed over a substrate 6011 is connected to a signal line driver circuit 6013 which is formed separately. The pixel portion 6012 and a scanning line driver circuit 6014 are each formed with a thin film transistor using a microcrystalline semiconductor film. By forming the signal line driver circuit with a thin film transistor by which higher mobility can be obtained as compared to the thin film transistor including the microcrystalline semiconductor film, operation of the signal line driver circuit, which demands a higher driving frequency than that of the scanning line driver circuit, can be stabilized. The signal line driver circuit 6013 may be formed using a thin film transistor using a single crystal semiconductor, a thin film transistor using a polycrystalline semiconductor, or a thin film transistor using an SOI. The pixel portion 6012, the signal line driver circuit 6013, and the scanning line driver circuit 6014 are each supplied with potential of a power source, various signals, and the like via an FPC 6015.

Note that the signal driver circuit and the scanning line driver circuit may both be formed over the same substrate as that of the pixel portion.

Alternatively, when the driver circuit is separately formed, a substrate provided with the driver circuit is not always required to be attached to a substrate provided with the pixel portion, and may be attached to, for example, the FPC. FIG. 26B shows a mode of a liquid crystal display device panel in which a pixel portion 6022 and a scanning line driver circuit 6024 formed over a substrate 6021 is connected to a signal line driver circuit 6023 which is formed separately. The pixel portion 6022 and the scanning line driver circuit 6024 are each formed with a thin film transistor using a microcrystalline semiconductor film. The signal line driver circuit 6023 is connected to the pixel portion 6022 via an FPC 6025. The pixel portion 6022, the signal line driver circuit 6023, and the scanning line driver circuit 6024 are each supplied with potential of a power source, various signals, and the like via the FPC 6025.

Alternatively, part of the signal line driver circuit or part of the scanning line driver circuit may be formed over the same substrate as that of the pixel portion with the thin film transistor using a microcrystalline semiconductor film, and the rest may be formed separately and electrically connected to the pixel portion. FIG. 26C shows a mode of a liquid crystal display panel in which an analog switch 6033a included in a signal line driver circuit is formed over a substrate 6031, which is the same substrate as a pixel portion 6032 and a scanning line driver circuit 6034, and a shift register 6033b included in the signal line driver circuit is separately formed over a different substrate and attached to the substrate 6031. The pixel portion 6032 and the scanning line driver circuit 6034 are each formed with the thin film transistor using a microcrystalline semiconductor film. The shift register 6033b included in the signal line driver circuit is connected to the pixel portion 6032 via an FPC 6035. The pixel portion 6032, the signal line driver circuit, and the scanning line driver circuit 6034 are each supplied with potential of a power source, various signals, and the like via the FPC 6035.

As shown in FIGS. 26A to 26C, in a liquid crystal display device of the present invention, all or part of the driver circuit can be formed over the same substrate as the pixel portion with the thin film transistor in which the microcrystalline semiconductor film is used.

Note that there is no particular limitation on a connection method of a separately formed substrate, and a known method such as a COG method, a wire bonding method, or a TAB method can be used. Further, a connection position is not limited to the positions shown in FIGS. 26A to 26C, as long as electrical connection is possible. Alternatively, a controller, a CPU, a memory, or the like may be formed separately and connected.

Note that the signal line driver circuit used in this embodiment mode is not limited to a mode including only a shift register and an analog switch. In addition to the shift register and the analog switch, another circuit such as a buffer, a level shifter, or a source follower may be included. In addition, the shift register and the analog switch are not always required to be provided, and, for example, a different circuit such as a decoder circuit by which selection of signal line is possible may be used instead of the shift register, and a latch or the like may be used instead of the analog switch.

This embodiment mode can be freely combined with Embodiment Mode 1, 2, 3, 4, 5, 6, 7, 8, 9, or 10.

### Embodiment Mode 12

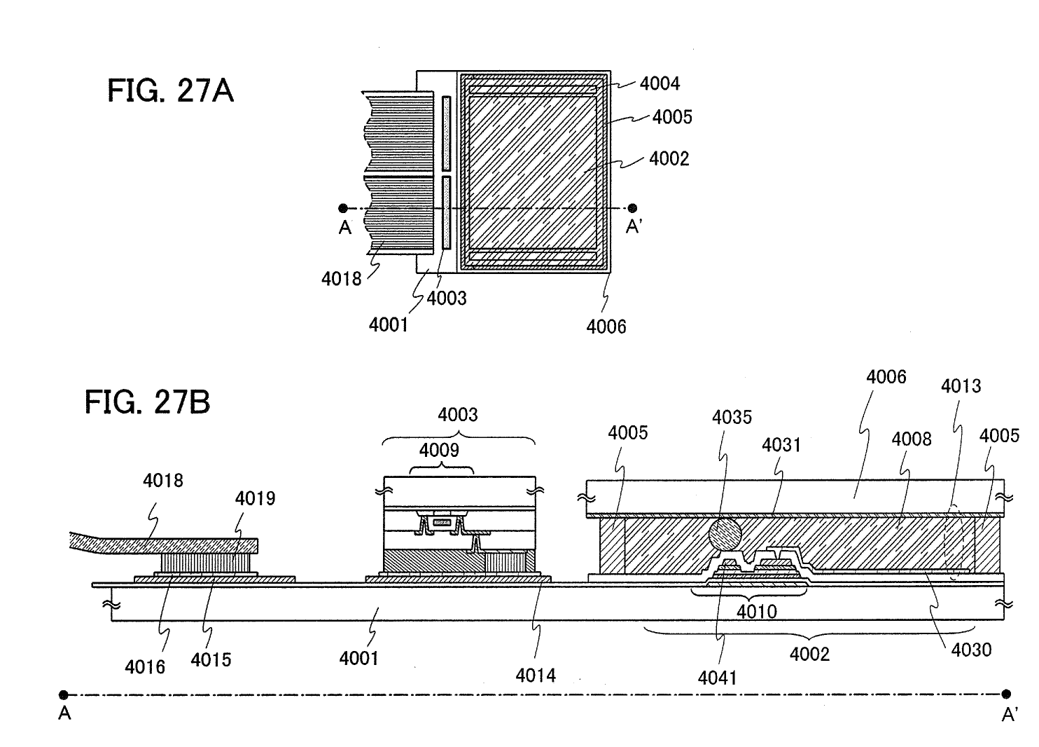

The appearance and a cross section of a liquid crystal display panel, which is one mode of the liquid crystal display device of the present invention, will be described with reference to FIGS. 27A and 27B. FIG. 27A is a top plan view of a panel. In the panel, a thin film transistor 4010 having a microcrystalline semiconductor film and a liquid crystal element 4013 which are formed over a first substrate 4001 are sealed between the first substrate 4001 and a second substrate 4006 by a sealant 4005. FIG. 27B is a cross-sectional view taken along line A-A′ in FIG. 27A.

The sealant 4005 is provided so as to surround a pixel portion 4002 and a scanning line driver circuit 4004 which are provided over the first substrate 4001. The second substrate 4006 is provided over the pixel portion 4002 and the scanning line driver circuit 4004. Therefore, the pixel portion 4002 and the scanning line driver circuit 4004 are sealed, together with liquid crystal 4008, between the first substrate 4001 and the second substrate 4006 with the sealant 4005. A signal line driver circuit 4003 formed over a substrate, which is prepared separately, using a polycrystalline semiconductor film is mounted at a region different from the region surrounded by the sealant 4005 over the first substrate 4001. Although an example in which the signal line driver circuit having a thin film transistor, which is formed using a polycrystalline semiconductor film, is attached to the first substrate 4001 is described in this embodiment mode, a signal line driver circuit having a thin film transistor, which is formed using a single crystal semiconductor film, may be attached to the first substrate 4001. FIGS. 27A and 27B show a thin film transistor 4009 formed using a polycrystalline semiconductor film, which is included in the signal line driver circuit 4003.

Each of the pixel portion 4002 and the scanning line driver circuit 4004 which are provided over the first substrate 4001 includes a plurality of thin film transistors. FIG. 27B shows the thin film transistor 4010 included in the pixel portion 4002. The thin film transistor 4010 corresponds to a thin film transistor which uses a microcrystalline semiconductor film.

Reference numeral 4011 denotes a liquid crystal element, and a pixel electrode 4030 included in the liquid crystal element 4013 is electrically connected to the thin film transistor 4010 through a wiring 4041. A counter electrode 4031 of the liquid crystal element 4013 is formed on the second substrate 4006. The liquid crystal element 4013 corresponds to a portion where the pixel electrode 4030 and the counter electrode 4031 sandwich the liquid crystal 4008.

Note that for the first substrate 4001 and the second substrate 4006, glass, metal (typically, stainless steel), ceramic or plastic can be used. As for plastic, an FRP (fiberglass-reinforced plastics) plate, a PVF (polyvinyl fluoride) film, a polyester film, or an acrylic resin film can be used. In addition, a sheet with a structure in which an aluminum foil is sandwiched between PVF films or polyester films can be used.

Reference numeral 4035 denotes a spherical spacer, which is provided to control a distance (a cell gap) between the pixel electrode 4030 and the counter electrode 4031. Note that a spacer obtained by selective etching of an insulating film may be used.

Various signals and potentials are supplied to the signal line driver circuit 4003 which is formed separately, the scanning line driver circuit 4004, or the pixel portion 4002 via a leading wiring 4014 and a leading wiring 4015 from an FPC 4018.

In this embodiment mode, a connection terminal 4016 is formed of the same conductive film as the pixel electrode 4030 included in the liquid crystal element 4013. In addition, the leading wirings 4014 and 4015 are formed of the same conductive film as the wiring 4041. As described in Embodiment Mode 1, with the use of a multi-tone mask, angles of the side faces of the leading wirings 4014 and 4015 are each wider than an angle of the side face of the wiring 4041. It is effective to process both of the side faces perpendicularly so that a short circuit does not occur between the adjacent leading wirings.

The connection terminal 4016 is electrically connected to a terminal of the FPC 4018 through an anisotropic conductive film 4019.

Although not shown, the liquid crystal display device shown in this embodiment mode includes an alignment film, a polarizing plate, and further, may include a color filter or a shielding film.

Although FIGS. 27A and 27B show an example in which the signal line driver circuit 4003 is separately formed and mounted on the first substrate 4001, this embodiment mode is not limited to this structure. The scanning line driver circuit may be separately formed and then mounted, or only part of the signal line driver circuit or part of the scanning line driver circuit may be separately formed and then mounted.

This embodiment mode can be implemented in combination with any of the structures of other embodiment modes.

### Embodiment Mode 13

The display device or the like obtained by the present invention can be used for an active matrix display device module. In other words, the present invention can be applied to all electronic devices incorporating them in display portions.

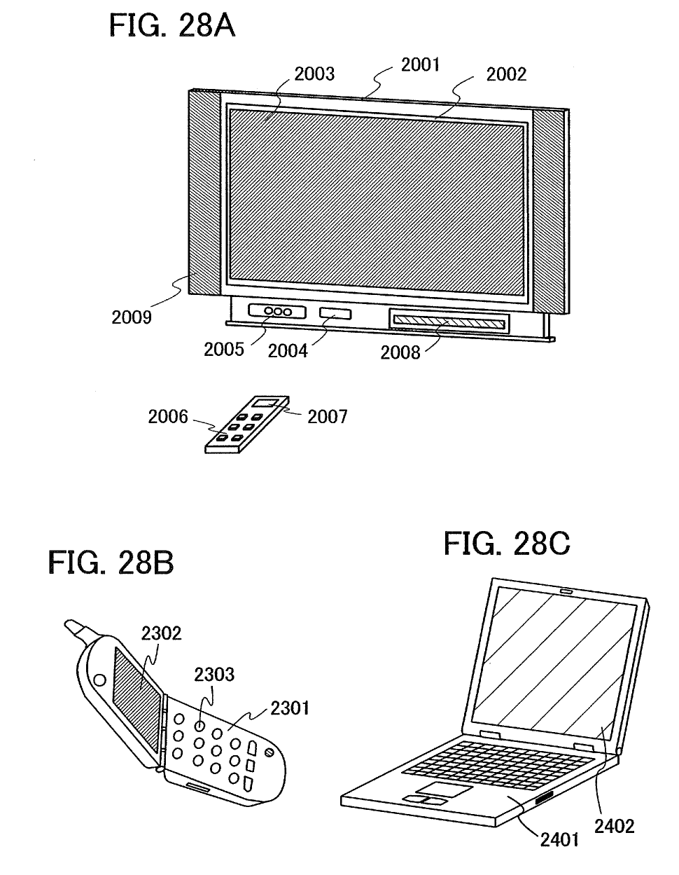

As examples of such electronic devices, the following can be given: a camera such as a video camera or a digital camera, a head mounted display (goggle type display), a car navigation system, a projector, a car stereo component, a personal computer, a portable information terminal (a mobile computer, a cellular phone, an electronic book, or the like), and the like. Examples of these electronic devices are shown in FIGS. 28A to 28C.

FIG. 28A shows a television set. A television set can be completed when a display module is incorporated into a housing, as shown in FIG. 28A. A display panel provided with components up to an FPC is also referred to as a display module. A main screen 2003 is formed of a display module, which is provided with a speaker portion 2009, operating switches, and the like as accessory equipment. In such a manner, a television set can be completed.

A display panel 2002 using a display element is incorporated into a housing 2001 as shown in FIG. 28A. In addition to reception of general TV broadcast with the use of a receiver 2005, communication of information can also be performed in one way (from a transmitter to a receiver) or in two ways (between a transmitter and a receiver or between receivers) by connection to a wired or wireless communication network through a modem 2004. The television set can be operated by using a switch which is incorporated into the housing or a remote control unit 2006 provided separately. In addition, a display portion 2007 for displaying output information may also be provided in the remote control unit.

Additionally, the television set may include a sub screen 2008 formed using a second display panel for displaying channels, volume, and the like, in addition to the main screen 2003. In this structure, the main screen 2003 may be formed with a liquid crystal display panel which has an excellent viewing angle, and the sub-screen 2008 may be formed with a light-emitting display panel by which display is possible with low power consumption. Alternatively, when reduction in power consumption is prioritized, a structure may be employed in which the main screen 2003 is formed using a light-emitting display panel, the sub-screen is formed using a light-emitting display panel, and the sub-screen can be turned on and off.

It is needless to say that the present invention is not limited to the television set and can be used as a large area display medium for various applications such as a monitor of a personal computer, information display boards at a train station, airport and the like, advertisement display boards on the streets, and the like.

FIG. 28B shows an example of a cellular phone 2301. The cellular phone 2301 includes a display portion 2302, operation switches 2303, and the like. The display device described in the above embodiment modes is applied to the display portion 2302, so that mass productivity can be improved.

In addition, a portable computer shown in FIG. 28C includes a main body 2401, a display portion 2402, and the like. The display device described in the above embodiment modes is applied to the display portion 2402, so that mass productivity can be improved.

The present application is based on Japanese Patent Application serial No. 2007-312818 filed with Japan Patent Office on Dec. 3, 2007, the entire contents of which are hereby incorporated by reference.

What is claimed is:

1. A semiconductor device comprising:
a semiconductor layer over a substrate; and
a wiring partially overlapping with the semiconductor layer,
wherein the wiring includes a region where the width of a wiring side portion is large and a region where the width of a wiring side portion is small, and
wherein the region where the width of a wiring side portion is large overlaps with at least part of the semiconductor layer, and an angle of the side face in a cross section in a wiring width direction is smaller than that of the region where the width of a wiring side portion is small by greater than or equal to 10°.

2. The semiconductor device according to claim 1, wherein the angle of the side face in a cross section in a wiring width direction of the region where the width of a wiring side portion is large is in the range of 10° to 50°.

3. The semiconductor device according to claim 1, wherein the angle of the side face in a cross section in a wiring width direction of the region where the width of a wiring side portion is small is in the range of 60° to 90°.

4. The semiconductor device according to claim 1, wherein the region where a wiring side portion is narrow does not overlap with the semiconductor layer.

5. A semiconductor device comprising:
a first wiring over a substrate;
an insulating film covering the first wiring; and
a second wiring electrically connected to the first wiring with <through> the insulating film interposed therebetween,
wherein, between two end portions of the second wiring in the cross-sectional shape, an angle of one side face with respect to a principal plane of the substrate is different from an angle of the other side face with respect to the principal plane of the substrate.

6. A semiconductor device according to claim 5, further comprising:
a transparent conductive film partially overlapping with the second wiring,
wherein, between two end portions of the second wiring in the cross-sectional shape, one side face where an angle with respect to the principal plane of the substrate is small is in contact with the transparent conductive film.

7. A semiconductor device comprising:
a first wiring and a second wiring having a cross-sectional shape different from that of the first wiring over the same insulating film surface,
wherein, a cross-sectional shape of the first wiring is a rectangle or a trapezoid,
wherein, the cross-sectional shape of the second wiring has a stair step in which one side face has two or more steps, and
wherein, the first wiring and the second wiring are formed of the same material.

8. A method for manufacturing a semiconductor device comprising the steps of:
forming a conductive layer over a substrate;
performing light exposure once using a multi-tone mask and developing a first resist mask and a second resist mask which are different in an angle between a side face in a cross section and a principal plane of the substrate; and
forming wirings by etching the conductive layer using the first resist mask and the second resist mask as masks,
wherein, after the development, a difference between an angle on the side face of the first resist mask and an angle on the side face of the second resist mask is greater than 10°.

9. The method for manufacturing a semiconductor device according to claim 8, wherein the cross-sectional shape of the first resist mask is a rectangle or a trapezoid, and the cross-sectional shape of the second resist mask is a trapezoid.

10. The method for manufacturing a semiconductor device according to claim 8,
